(19) United States
(12) Patent Application Publication
(10) Pub. No.: US 2023/0284486 A1
(43) Pub. Date: Sep. 7, 2023

(54) DISPLAY PANEL, METHOD OF MANUFACTURING THE SAME, AND ELECTRONIC DEVICE INCLUDING THE SAME

(71) Applicant: Samsung Display Co., Ltd., Yongin-si (KR)

(72) Inventor: KEE-BUM PARK, Cheonan-si (KR)

(21) Appl. No.: 18/175,454

(22) Filed: Feb. 27, 2023

(30) Foreign Application Priority Data
Mar. 3, 2022 (KR) 10-2022-0027713

(51) Int. Cl. H10K 59/123; H10K 59/65; H10K 59/122; H10K 59/80; H10K 59/124; H10K 59/12; H10K 71/60; H10K 59/131

(52) U.S. Cl. CPC H10K 59/123; H10K 59/65; H10K 59/122; H10K 59/873; H10K 59/124; H10K 59/1201; H10K 71/60; H10K 59/131

(57) ABSTRACT

A display panel includes: a base substrate having a hole defined therethrough; a thin film transistor on the base substrate, and spaced from the hole; a light emitting element including a pixel electrode spaced from the hole, and connected to the thin film transistor; a first insulating layer between the base substrate and the pixel electrode, and having a groove pattern defined therein between the pixel electrode and the hole in a plan view; a first conductive pattern spaced from the pixel electrode, and including a tip portion defining a first pattern hole overlapping with the groove pattern; and a second conductive pattern spaced from the pixel electrode, and having a second pattern hole defined therethrough, and overlapping with the first pattern hole.

### CROSS-REFERENCE TO RELATED APPLICATION

This application claims priority to and the benefit of Korean Patent Application No. 10-2022-0027713, filed on Mar. 3, 2022, the entire content of which is incorporated by reference herein.

### BACKGROUND

### 1. Field

Aspects of one or more embodiments of the present disclosure relate to a display panel including a hole defined therethrough, a method of manufacturing the display panel, and an electronic device including the display panel.

### 2. Description of the Related Art

Electronic devices that provide an image to a user, such as a television, a mobile phone, a tablet computer, a computer, a navigation unit, and a game unit, include a display panel to generate and display the image. The electronic devices include various electronic components, such as an input sensor, an electronic module, and the like, in addition to the display panel. As an example, the electronic module includes a camera, an infrared sensor, and/or a proximity sensor.

In recent years, research conducted on a method of increasing a display area and decreasing a non-display area are ongoing in order to provide a wider display surface to a user.

The above information disclosed in this Background section is for enhancement of understanding of the background of the present disclosure, and therefore, it may contain information that does not constitute prior art.

### SUMMARY

As an example for widening a display surface, the electronic module may be disposed under (e.g., underneath) the display panel, and a hole may be defined through the display panel to expose the electronic module.

One or more embodiments of the present disclosure are directed to a display panel including a tip portion having a desired length (e.g., a predetermined length), while preventing or substantially preventing the tip portion from being damaged by using a simplified process.

One or more embodiments of the present disclosure are directed to a display panel capable of preventing or substantially preventing moisture and/or oxygen from entering light emitting elements through the tip portion, and thus, having improved reliability.

According to one or more embodiments of the present disclosure, a display panel includes: a base substrate having a hole defined therethrough; a thin film transistor on the base substrate, and spaced from the hole; a light emitting element including a pixel electrode spaced from the hole, and connected to the thin film transistor; a first insulating layer between the base substrate and the pixel electrode, and having a groove pattern defined therein between the pixel electrode and the hole in a plan view; a first conductive pattern spaced from the pixel electrode, and including a tip portion defining a first pattern hole overlapping with the groove pattern; and a second conductive pattern spaced from the pixel electrode, and having a second pattern hole defined therethrough, and overlapping with the first pattern hole.

In an embodiment, the second conductive pattern may be at a same layer as that of the pixel electrode.

In an embodiment, the second conductive pattern may include a same material as that of the pixel electrode.

In an embodiment, the second conductive pattern may include a material different from a material of the first conductive pattern.

In an embodiment, the tip portion may have a side surface defining the first pattern hole, and protruding more toward a center of the first pattern hole than an inner side surface of the first insulating layer defining the groove pattern.

In an embodiment, the first conductive pattern may include a plurality of conductive layers, and the side surface of the tip portion may be defined by side surfaces of the conductive layers.

In an embodiment, the second pattern hole may have a width greater than a width of the first pattern hole in a plan view.

In an embodiment, the groove pattern may surround the hole in a plan view.

In an embodiment, the display panel may further include a connection electrode connecting the thin film transistor to the pixel electrode, and the first conductive pattern may be at a same layer as that of the connection electrode.

In an embodiment, the first conductive pattern may include a same material as that of the connection electrode.

In an embodiment, the display panel may further include a pixel definition layer having a light emitting opening defined therethrough to expose at least a portion of the pixel electrode, and a first opening defined therethrough to expose at least a portion of the second conductive pattern.

In an embodiment, the second conductive pattern may include one side surface defining the second pattern hole, and another side surface opposite to the one side surface, and the one side surface may be exposed through the first opening, and the other side surface may be covered by the pixel definition layer.

In an embodiment, the display panel may further include an encapsulation layer on the light emitting element, and including: a plurality of inorganic layers; and an organic layer between the inorganic layers. At least one of the inorganic layers may cover an inner side surface of the first insulating layer that defines the groove pattern.

In an embodiment, the at least one of the inorganic layers may cover a side surface of the tip portion that defines the first pattern hole.

In an embodiment, the groove pattern may include a plurality of groove patterns, at least one of the plurality of groove patterns may overlap with the organic layer, and another of the plurality of groove patterns may be spaced from the organic layer.

In an embodiment, the display panel may further include a second insulating layer between the pixel electrode and the first insulating layer, and the second insulating layer may be between the first conductive pattern and the second conductive pattern, and may have a second opening defined therethrough, and overlapping with the first pattern hole in a plan view.

According to one or more embodiments of the present disclosure, an electronic device includes: a base substrate including: a hole area having a hole; a display area surrounding at least a portion of the hole area in a plan view; and a non-display area adjacent to the display area in a plan view; a thin film transistor on the base substrate, and spaced from the hole; a light emitting element including a pixel electrode at the display area, and connected to the thin film transistor; a first insulating layer between the base substrate and the light emitting element, and having a groove pattern defined therein and overlapping with the hole area; a first conductive pattern on the first insulating layer, overlapping with the hole area, and including a tip portion defining a first pattern hole overlapping with the groove pattern; a second conductive pattern at a layer different from a layer of the first conductive pattern, overlapping with the hole area, and having a second pattern hole defined therethrough and overlapping with the first pattern hole; and an electronic module overlapping with the hole area.

According to one or more embodiments of the present disclosure, a method of manufacturing a display panel, includes: providing a target substrate including a base substrate, and a first insulating layer on the base substrate, the base substrate including a hole area, and a display area surrounding the hole area; forming a first conductive pattern including a first pattern hole defined therethrough, the first pattern hole exposing a portion of the first insulating layer overlapping with the hole area; forming a conductive layer covering the display area, the first conductive pattern, and the portion of the first insulating layer; forming a preliminary second conductive pattern overlapping with the first pattern hole, and a pixel electrode spaced from the preliminary second conductive pattern, from the conductive layer; forming a second conductive pattern from the preliminary second conductive pattern, the second conductive pattern including a second pattern hole defined therethrough, and overlapping with the first pattern hole; and forming a groove pattern in the first insulating layer to overlap with the first pattern hole. The preliminary second conductive pattern covers a side surface of the first conductive pattern defining the first pattern hole.

In an embodiment, the second preliminary conductive pattern and the pixel electrode may be formed by wet-etching the conductive layer, and the groove pattern may be formed by dry-etching the first insulating layer.

In an embodiment, a side surface of the first conductive pattern defining the first pattern hole may protrude more toward a center of the first pattern hole than an inner side surface of the first insulating layer defining the groove pattern.

According to one or more embodiments of the present disclosure, the tip portion may have a desired length (e.g., a predetermined length), and may effectively block a continuity of functional layers at (e.g., in or on) the hole area of the display panel. The inorganic layer is deposited on the tip portion and the groove pattern. Thus, a path of moisture and/or oxygen through the hole area of the display panel may be blocked.

According to one or more embodiments of the present disclosure, the tip portion may be protected by the conductive pattern during the process of forming the tip portion. Thus, the tip portion may be prevented or substantially prevented from being damaged, and the tip portion may have the desired length (e.g., the predetermined length). In addition, because the tip portion may be protected by the conductive pattern, an occurrence of additional contamination may be prevented or substantially prevented.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIG. 1 is a perspective view of an electronic device according to an embodiment of the present disclosure;

FIG. 2 is an exploded perspective view of an electronic device according to an embodiment of the present disclosure;

FIG. 3 is a plan view of a display panel according to an embodiment of the present disclosure;

FIG. 4 is an enlarged plan view of an area of a display panel according to an embodiment of the present disclosure;

FIG. 5 is a cross-sectional view of a display panel taken along the line I-I′ of FIG. 4;

FIGS. 6A-6B are enlarged cross-sectional views of a display panel according to one or more embodiments of the present disclosure;

FIG. 7 is a flowchart of a method of manufacturing a display panel according to an embodiment of the present disclosure; and

FIGS. 8A-8K are cross-sectional views of a method of manufacturing a display panel according to an embodiment of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer, or section. Thus, a first element, component, region, layer, or section described below could be termed a second element, component, region, layer, or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively. Also, the term “exemplary” is intended to refer to an example or illustration.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

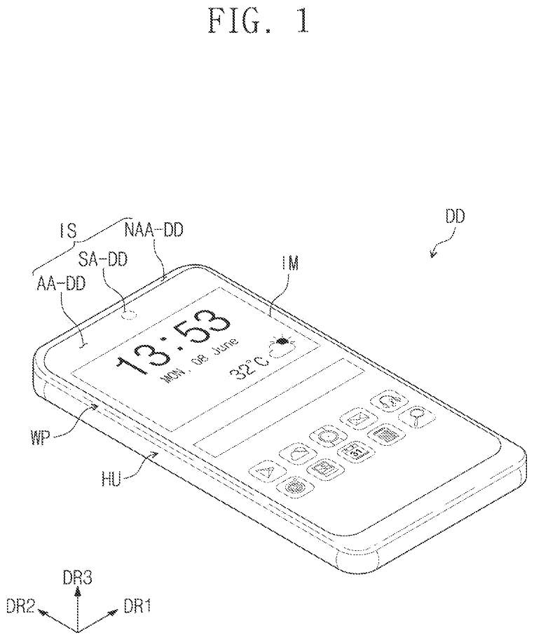

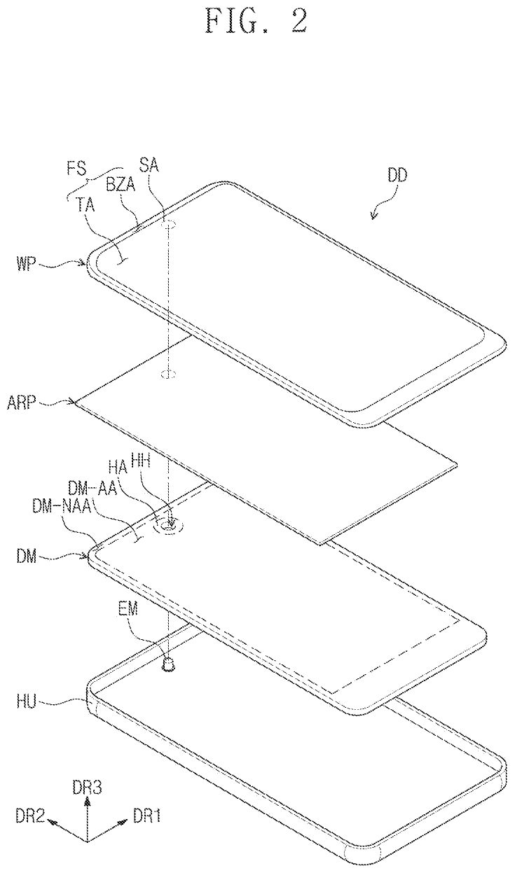

FIG. 1 is a perspective view of an electronic device DD according to an embodiment of the present disclosure. FIG. 2 is an exploded perspective view of the electronic device DD according to an embodiment of the present disclosure.

The electronic device DD may be activated in response to electrical signals, and may display an image IM. The electronic device DD may include various suitable electronic apparatuses to provide the image IM to a user. As an example, the electronic device DD may be applied to a large-sized electronic apparatus, such as a television set, an outdoor billboard, and the like. As another example, the electronic device DD may be applied to a small-sized and/or a medium-sized electronic apparatus, such as a monitor, a mobile phone, a tablet computer, a computer, a navigation unit (e.g., a navigation device or console), a game unit (e.g., a game device or console), and the like. However, the present disclosure is not limited thereto, and the electronic device DD may be applied to other suitable electronic devices and apparatuses.

Referring to FIG. 1, the electronic device DD may have a rectangular shape, with short sides extending in a first direction DR1, and long sides extending in a second direction DR2 crossing the first direction DR1. However, the shape of the electronic device DD is not limited to the rectangular shape, and the electronic device DD may have various suitable shapes, such as a circular shape, another polygonal shape, or the like.

The electronic device DD may display the image IM through a display surface IS toward a third direction DR3, which is perpendicular to or substantially perpendicular to a plane defined by the first direction DR1 and the second direction DR2. A normal line direction of the display surface IS may be parallel to or substantially parallel to the third direction DR3. The display surface IS of the electronic device DD may correspond to a front surface of the electronic device DD.

The image IM displayed through the electronic device DD may include a still image as well as a video. FIG. 1 shows a clock widget and application icons as representative examples of the image IM.

In the present embodiment, a front (e.g., an upper) surface and a rear (e.g., a lower) surface of each member (e.g., each element, component, layer, unit, and the like) of the electronic device DD may be defined with respect to a direction in which the image IM is displayed. The front and rear surfaces may be opposite to each other in the third direction DR3, and a normal line direction of each of the front and rear surfaces may be parallel to or substantially parallel to the third direction DR3. A separation distance between the front and rear surfaces of each member in the third direction DR3 may correspond to a thickness of the member.

As used in the present disclosure, the expressions “viewed in a plane” and “in a plan view” may refer to a state of being viewed in the third direction DR3. As used in the present disclosure, the expressions “viewed in a cross-section” and “in a cross-sectional view” may refer to a state of being viewed in the first direction DR1 or the second direction DR2. However, the directions indicated by the first, second, and third directions DR1, DR2, and DR3 are relative to each other, and thus, the directions indicated by the first, second, and third directions DR1, DR2, and DR3 may be variously modified to other suitable directions.

The electronic device DD may be flexible. The term “flexible” as used herein refers to a property of being able to be bent from a structure that is completely bent to a structure that is bent at a scale of a few nanometers. For example, the electronic device DD may be a curved electronic device, or a foldable electronic device. According to an embodiment, the electronic device DD may be rigid.

FIG. 1 shows the electronic device DD including a flat or substantially flat display surface IS as a representative example. However, the shape of the display surface IS of the electronic device DD is not limited thereto or thereby, and the display surface IS may have a curved shape or a three-dimensional shape.

The display surface IS of the electronic device DD may include a display part AA-DD and a non-display part NAA-DD. The display part AA-DD may be a part where the image IM is displayed within the front surface of the electronic device DD, and a user may view the image IM through the display part AA-DD. In the present embodiment, the display part AA-DD having a quadrangular shape in a plane (e.g., in a plan view) is illustrated as a representative example. However, the display part AA-DD may have various suitable shapes depending on a design of the electronic device DD.

The non-display part NAA-DD may be a part where the image IM is not displayed within the front surface of the electronic device DD. The non-display part NAA-DD may have a suitable color (e.g., a predetermined color), and may block light. The non-display part NAA-DD may be disposed adjacent to the display part AA-DD. As an example, the non-display part NAA-DD may be disposed outside of the display part AA-DD, and may surround (e.g., around a periphery of) the display part AA-DD. However, the present disclosure is not limited thereto. The non-display part NAA-DD may be defined to be adjacent to only one side of the display part AA-DD, or may be defined at (e.g., in or on) a side surface of the electronic device DD, rather than at (e.g., in or on) the front surface of the electronic device DD. According to an embodiment, the non-display part NAA-DD may be omitted.

According to an embodiment, the display part AA-DD of the electronic device DD may include a sensing area SA-DD defined therein. The sensing area SA-DD may correspond to an area overlapping with an electronic module (e.g., an electronic device or sensor) EM (e.g., refer to FIG. 2). The electronic module EM may receive external signals, or may provide signals to the outside through the sensing area SA-DD. FIGS. 1 and 2 show one sensing area SA-DD disposed at (e.g., in or on) the display part AA-DD as a representative example, but the present disclosure is not limited thereto or thereby. According to an embodiment, the sensing area SA-DD may be provided in a plurality at (e.g., in or on) the display part AA-DD.

According to an embodiment, the electronic device DD may sense an external input applied thereto from the outside. The external input may include various suitable external inputs provided from the outside, such as pressure, temperature, light, and/or the like. The external input may include a proximity input (e.g., a hovering input) applied when an object (e.g., a hand of a user or a pen) approaches close to or adjacent to the electronic device DD at a suitable distance (e.g., a predetermined distance), as well as a touch input (e.g., a touch by the hand of the user or the pen).

Referring to FIGS. 1 and 2, the electronic device DD may include a window WP and a housing HU. The window WP and the housing HU may be coupled to (e.g., connected to or attached to) each other to provide an exterior of the electronic device DD, and may provide an inner space in which the components of the electronic device DD are accommodated. The electronic device DD may include a display module (e.g., a display or a touch-display) DM, an anti-reflective member ARP and the electronic module EM, which are disposed between the window WP and the housing HU.

The electronic module EM may be disposed under (e.g., underneath) the display module DM. The electronic module EM may be disposed to overlap with the display module DM. The electronic module EM may be an electronic component that outputs and/or receives an optical signal. For example, the electronic module EM may be a camera module (e.g., a camera) that photographs an image of an external object, but is not limited thereto or thereby. According to an embodiment, the electronic module may be a sensor module (e.g., a sensor), such as a proximity sensor or an infrared ray emission sensor.

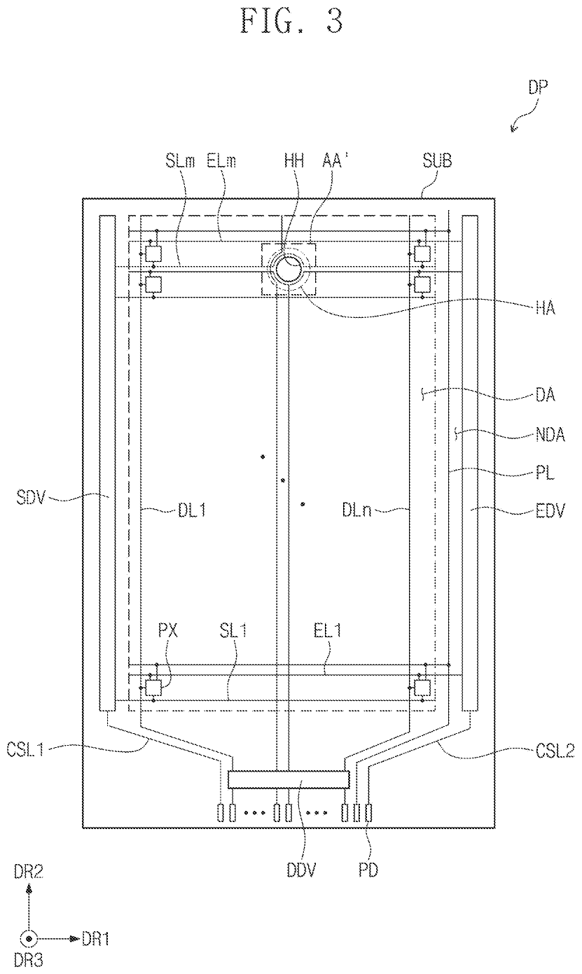

The display module DM may be disposed on the electronic module EM. The display module DM may include a display panel DP (e.g., refer to FIG. 3), which will be described in more detail below. The display panel DP may generate images in response to electrical signals. The display panel DP may be a light emitting type display panel, but is not limited thereto or thereby.

The display module DM may further include an input sensor disposed on the display panel DP. The input sensor may obtain coordinate information of the external input applied thereto from the outside of the electronic device DD. The input sensor may be driven in various suitable methods, such as a capacitive method, a resistive method, an infrared ray method, a pressure method, or the like, but the present disclosure is not particularly limited thereto.

The input sensor may be disposed directly on the display panel DP. The input sensor may be coupled with (e.g., connected to or attached to) the display panel DP without a separate adhesive member. In other words, the input sensor may be formed on a base surface provided by the display panel DP through successive processes, but the present disclosure is not limited thereto or thereby. According to an embodiment, the input sensor may be coupled with (e.g., connected to or attached to) the display panel DP by an adhesive member, after being manufactured through a separate process from that of the display panel DP.

The display module DM may include an active area DM-AA, and a peripheral area DM-NAA adjacent to the active area DM-AA. The active area DM-AA may be activated in response to electrical signals. The peripheral area DM-NAA may surround (e.g., around a periphery of) the active area DM-AA. A driving circuit or a driving line to drive elements disposed at (e.g., in or on) the active area DM-AA, various signal lines to provide electrical signals to the elements, and pads may be disposed at (e.g., in or on) the peripheral area DM-NAA.

The display module DM may include a hole area HA within the active area DM-AA. The hole area HA may correspond to the sensing area SA-DD. As used in the present disclosure, the expression “an area/portion corresponds to another area/portion” means that “the area/portion overlaps with the other area/portion”, and the “areas and portions” are not limited to having the same size as those of “the other areas and portions”.

The hole area HA may overlap with the electronic module EM. At least a portion of the hole area HA may be surrounded (e.g., around a periphery thereof) by the active area DM-AA. For example, the hole area HA may be completely surrounded (e.g., around a periphery thereof) by the active area DM-AA, but is not limited thereto or thereby. According to an embodiment, a portion of the hole area HA may be surrounded (e.g., around a periphery thereof) by the active area DM-AA, and another portion of the hole area HA may be in contact with the peripheral area DM-NAA.

A hole HH may be defined through the display panel DP (e.g., refer to FIG. 3) in the hole area HA. The hole HH may overlap with the electronic module EM. A portion of the electronic module EM may be inserted into the hole HH.

The anti-reflective member ARP may be disposed between the display module DM and the window WP. The anti-reflective member ARP may reduce a reflectance with respect to external light incident thereto from the outside of the electronic device DD. In other words, the anti-reflective member ARP may reduce the reflectance of the electronic device DD with respect to the external light. The anti-reflective member ARP may include a polarizer, a retarder, a destructive interference structure, a plurality of color filters, and/or the like.

A portion of the anti-reflective member ARP, which overlaps with the hole area HA, may have a relatively high light transmittance. As an example, the anti-reflective member ARP may include a transmission portion overlapping with the hole area HA, or the anti-reflective member ARP may be provided with a through hole defined (e.g., penetrating) therethrough, and overlapping with the hole area HA.

The window WP may be disposed on the anti-reflective member ARP. The window WP may protect the display module DM and the anti-reflective member ARP, which are disposed under (e.g., underneath) the window WP.

The window WP may include an optically transparent insulating material. As an example, the window WP may include glass, sapphire, or a plastic material. The window WP may have a single-layer structure or a multi-layered structure. The window WP may further include a functional layer, such as an anti-fingerprint layer, a phase control layer, a hard coating layer, and/or the like, disposed on an optically transparent substrate.

A front surface FS of the window WP may correspond to the display surface IS of the electronic device DD. The front surface FS of the window WP may include a transmission area TA and a bezel area BZA.

The transmission area TA of the window WP may be an optically transparent area. The transmission area TA of the window WP may correspond to the display part AA-DD of the electronic device DD. The transmission area TA may overlap with at least a portion of the active area DM-AA of the display module DM. The window WP may transmit the image IM provided from the display module DM through the transmission area TA, and the user may view the image IM.

The transmission area TA of the window WP may include a sensing area SA. The sensing area SA of the window WP may correspond to the sensing area SA-DD of the electronic device DD. The sensing area SA of the window WP may overlap with the hole area HA and the electronic module EM. The sensing area SA of the window WP may have a relatively high light transmittance. Accordingly, the electronic module EM may effectively receive the external input, or may effectively output the signal through the sensing area SA.

The bezel area BZA of the window WP may be obtained by depositing, coating, or printing a material having a suitable color (e.g., a predetermined color) on a transparent substrate. The bezel area BZA may correspond to the non-display part NAA-DD (e.g., refer to FIG. 1) of the electronic device DD. The bezel area BZA may overlap with at least a portion of the peripheral area DM-NAA of the display module DM. As the bezel area BZA of the window WM covers the peripheral area DM-NAA of the display module DM, the components of the display module DM that are disposed at (e.g., in or on) the peripheral area DM-NAA may be prevented or substantially prevented from being viewed from the outside.

The housing HU may be disposed under (e.g., underneath) the display module DM. The housing HU may protect the components accommodated therein. The housing HU may prevent or substantially prevent foreign substances and/or moisture from entering the display module DM and the anti-reflective member ARP. The housing HU may include a material having a relatively high strength, and may absorb impacts applied thereto from the outside of the housing HU. According to an embodiment, the housing HU may be provided in a form obtained by coupling (e.g., connecting or attaching) a plurality of accommodating members with one another.

FIG. 3 is a plan view of the display panel DP according to an embodiment of the present disclosure. FIG. 3 schematically shows some of the components of the display panel DP when viewed in a plane (e.g., in a plan view).

The display panel DP may be a light-emitting type display panel. For example, the display panel DP may be an organic light emitting display panel, an inorganic light emitting display panel, or a quantum dot light emitting display panel. A light emitting layer of the organic light emitting display panel may include an organic light emitting material. A light emitting layer of the inorganic light emitting display panel may include an inorganic light emitting material. A light emitting layer of the quantum dot light emitting display panel may include a quantum dot and/or a quantum rod. Hereinafter, for convenience, the organic light emitting display panel will be described in more detail as a representative example of the display panel DP.

Referring to FIG. 3, the display panel DP may include a base substrate SUB, a plurality of pixels PX, a plurality of signal lines SL1 to SLm, DL1 to DLn, EL1 to ELm, CSL1, CSL2, and PL electrically connected to the pixels PX, a scan driver SDV, a data driver DDV, an emission driver EDV, and a plurality of pads PD, where m and n are natural numbers.

The base substrate SUB may provide a base surface on which the elements and lines of the display panel DP are disposed. FIG. 3 shows the base substrate SUB having a rectangular shape that is parallel to or substantially parallel to each of the first direction DR1 and the second direction DR2 when viewed in a plane (e.g., in a plan view) as a representative example, but the shape of the base substrate SUB is not limited thereto or thereby. According to an embodiment, the base substrate SUB may be manufactured in various suitable shapes depending on a design of the electronic device DD (e.g., refer to FIG. 1).

The base substrate SUB may include a display area DA and a non-display area NDA. The display area DA may correspond to the active area DM-AA of the display module DM. The non-display area NDA may correspond to the peripheral area DM-NAA of the display module DM. The display area DA may be an area through which the image IM is displayed, and the non-display area NDA may be an area through which no image is displayed. A driver and a line to drive light emitting elements disposed at (e.g., in or on) the display area DA may be arranged at (e.g., in or on) the non-display area NDA.

The base substrate SUB may be provided with the hole area HA, at least a portion thereof being surrounded (e.g., around a periphery thereof) by the display area DA. The hole HH may be defined (e.g., may penetrate) through the display panel DP in the hole area HA. The hole HH may be defined (e.g., may penetrate) through the base substrate SUB. A portion of the electronic module EM (e.g., refer to FIG. 2) may be inserted into the hole HH.

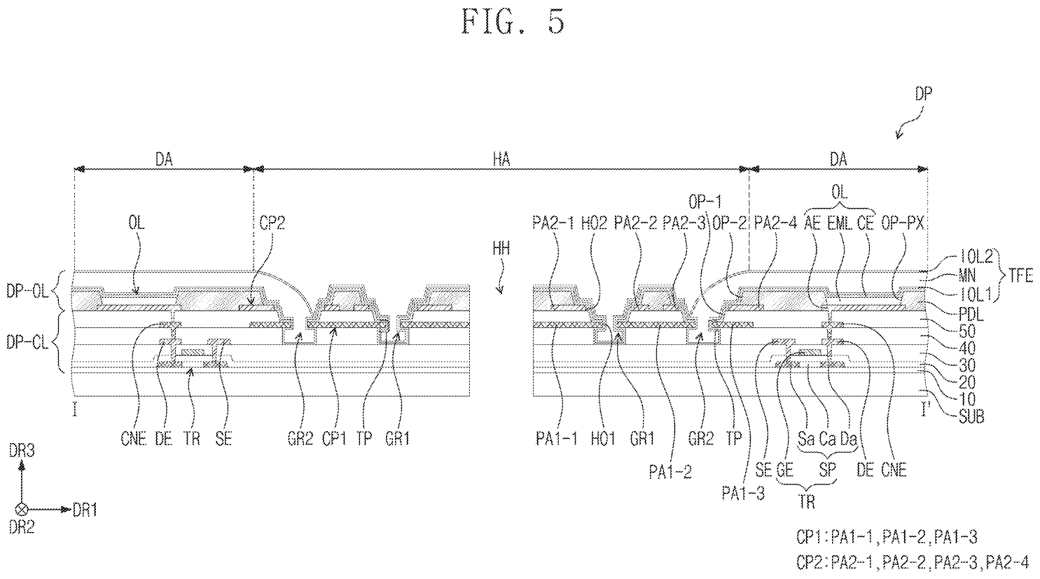

The pixels PX may be disposed to be spaced apart from the hole area HA at (e.g., in or on) the display area DA. In more detail, a pixel electrode AE (e.g., refer to FIG. 5) of a light emitting element OL forming the pixels PX may be disposed to be spaced apart from the hole area HA. The optical signal may be provided from the electronic module EM (e.g., refer to FIG. 2) to the outside via the hole area HA, or may be provided to the electronic module EM from the outside via the hole area HA. The hole area HA may have a light transmittance relatively higher than that of the display area DA in which the pixels PX are disposed.

Some signal lines of the signal lines SL1 to SLm, DL1 to DLn, EL1 to ELm, CSL1, CSL2, and PL may extend at (e.g., in or on) the display area DA via the hole area HA. Accordingly, the some signal lines may include a curved line extending along a boundary of the hole HH, but the present disclosure is not limited thereto or thereby. According to an embodiment, a separate bridge pattern distinguished from the signal line may be disposed at (e.g., in or on) the hole area HA, and the some signal lines may be connected to the bridge pattern. In this case, the some signal lines may be disposed at (e.g., in or on) the same layer as that of the bridge pattern to be directly connected to the bridge pattern, or may be disposed at (e.g., in or on) a layer different from that of the bridge pattern to be connected to the bridge pattern via a contact hole.

The signal lines SL1 to SLm, DL1 to DLn, EU to ELm, CSL1, CSL2, and PL may pass through the hole area HA in various suitable methods. According to an embodiment, as the signal lines SL1 to SLm, DL1 to DLn, EL1 to ELm, CSL1, CSL2, and PL transmit electrical signals via the hole area HA, the electrical signals may be provided to an entirety of the display area DA, without being interrupted by the hole HH.

The display panel DP may include conductive patterns and a groove pattern, which are disposed at (e.g., in or on) the hole area HA, and spaced apart from the pixels PX. Accordingly, the display panel DP may prevent or substantially prevent moisture and/or oxygen from entering the pixels PX via the hole HH, and the reliability of the display panel DP may be improved. This will be described in more detail below.

Each of the pixels PX may include a light emitting element, and a pixel driving circuit configured with a plurality of thin film transistors (e.g., a switching transistor, a driving transistor, and/or the like) connected to the light emitting element, and at least one capacitor. Each of the pixels PX may be arranged at (e.g., in or on) the display area DA, and may emit light in response to an electrical signal applied thereto, but the present disclosure is not limited thereto. According to an embodiment, thin film transistors of some of the pixels PX from among the pixels PX may be disposed at (e.g., in or on) the non-display area NDA.

Each of the scan driver SDV, the data driver DDV, and the emission driver EDV may be disposed at (e.g., in or on) the non-display area NDA of the display panel DP, but the present disclosure is not limited thereto or thereby. According to an embodiment, at least one of the scan driver SDV, the data driver DDV, or the emission driver EDV may be disposed to overlap with the display area DA.

The data driver DDV may be manufactured in an integrated circuit (IC) chip form, and may be mounted on the non-display area NDA of the display panel DP, but the present disclosure is not limited thereto or thereby. According to an embodiment, the data driver DDV may be electrically connected to the display panel DP after being mounted on a separate flexible circuit board that is connected to the display panel DP.

The signal lines SL1 to SLm, DL1 to DLn, EL1 to ELm, CSL1, CSL2, and PL may include a plurality of scan lines SL1 to SLm, a plurality of data lines DL1 to DLn, a plurality of emission lines EL1 to ELm, first and second control lines CSL1 and CSL2, and a power line PL. Here, each of m and n is a natural number.

The scan lines SL1 to SLm may extend in the first direction DR1, and may be connected to the scan driver SDV. The data lines DL1 to DLn may extend in the second direction DR2, and may be connected to the data driver DDV. The emission lines EL1 to ELm may extend in the first direction DR1, and may be connected to the emission driver EDV.

The power line PL may extend in the second direction DR2, and may be disposed at (e.g., in or on) the non-display area NDA. The power line PL may be disposed between the display area DA and the emission driver EDV, but an arrangement position of the power line PL is not limited thereto or thereby. The power line PL may be electrically connected to the pixels PX via connection lines connected to the pixels PX, and may apply a suitable voltage (e.g., a predetermined voltage) to the pixels PX. The power line PL may be disposed at (e.g., in or on) a layer different from that of the connection lines and may be connected to the connection lines via contact holes, or may be provided integrally with the connection lines at (e.g., in or on) the same layer as that of the connection lines.

The first control line CSL1 may be connected to the scan driver SDV. The second control line CSL2 may be connected to the emission driver EDV.

The pads PD may be disposed adjacent to a lower end of the non-display area NDA. The pads PD may be disposed closer to the lower end of the display panel DP than the data driver DDV. The pads PD may be arranged along the first direction DR1. The electronic device DD (e.g., refer to FIG. 1) may include a circuit board including a timing controller to control an operation of the scan driver SDV, the data driver DDV, and the emission driver EDV, and a voltage generator to generate a voltage. The pads PD may be connected to the circuit board of the electronic device DD.

Each of the pads PD may be connected to corresponding signal lines from among the signal lines SL1 to SLm, DL1 to DLn, EL1 to ELm, CSL1, CSL2, and PL. The data lines DL1 to DLn, the power line PL, and the first and second control lines CSL1 and CSL2 may be electrically connected to the pads PD. As an example, the data lines DL1 to DLn may be connected to the data driver DDV, and the data driver DDV may be electrically connected to the pads PD corresponding to the data lines DL1 to DLn, respectively.

The scan driver SDV may generate a plurality of scan signals in response to a scan control signal. The scan signals may be applied to the pixels PX via the scan lines SL1 to SLm. The data driver DDV may generate a plurality of data voltages corresponding to image signals in response to a data control signal. The data voltages may be applied to the pixels PX via the data lines DL1 to DLn. The emission driver EDV may generate a plurality of emission signals in response to an emission control signal. The emission signals may be applied to the pixels PX via the emission lines EU to ELm.

The pixels PX may receive the data voltages in response to the scan signals. The pixels PX may emit a light having a desired luminance corresponding to the data voltages in response to the emission signals, and thus, the image may be displayed. An emission time of the pixels PX may be controlled by the emission signals. Accordingly, the display panel DP may display the image through the display area DA using the pixels PX.

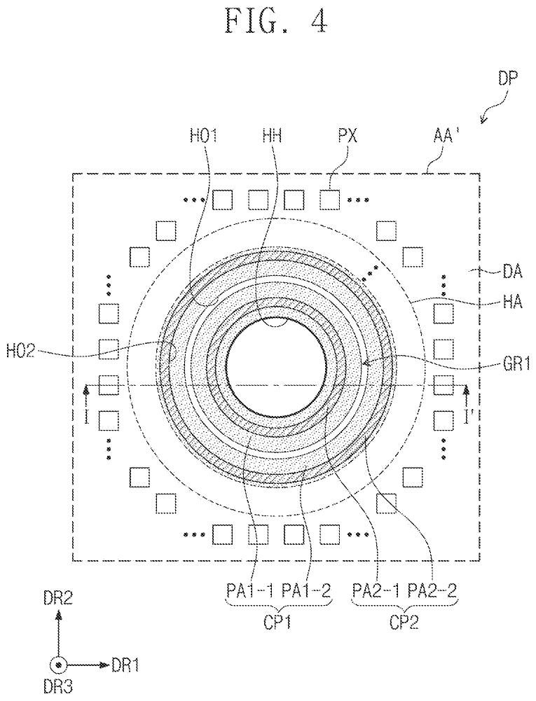

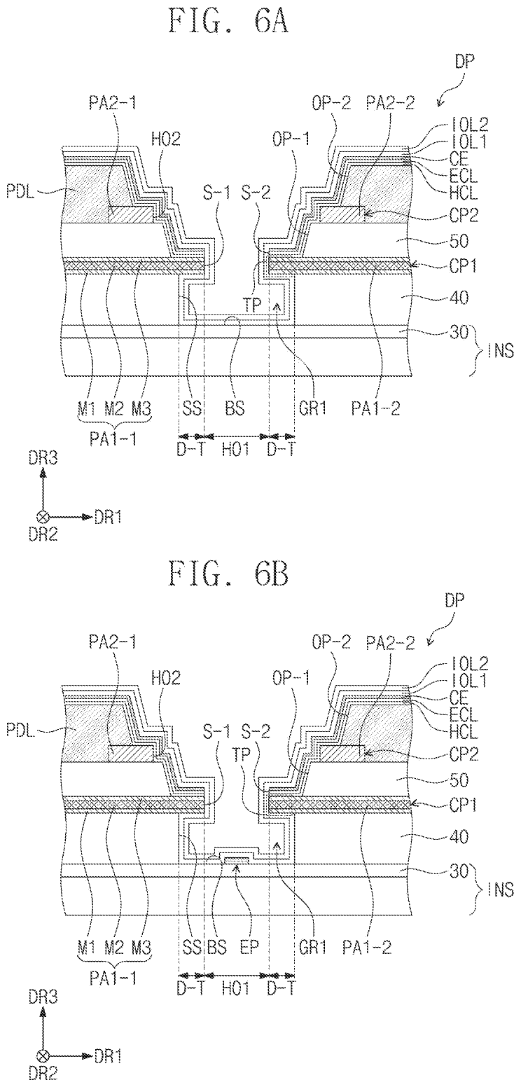

FIG. 4 is an enlarged plan view of an area of the display panel DP according to an embodiment of the present disclosure. For example, FIG. 4 may be an enlarged plan view of the area AA′ of the display panel DP shown in FIG. 3. FIG. 5 is a cross-sectional view of the display panel DP taken along the line I-I′ of FIG. 4. FIGS. 6A and 6B are enlarged cross-sectional views of the display panel DP according to one or more embodiments of the present disclosure. The area AA′ of FIG. 4 may correspond to a portion of the display area DA including the hole area HA (e.g., see FIG. 3), and the hole area HA and some components of the display panel DP that are disposed adjacent to the hole area HA are briefly illustrated in FIG. 4.

Referring to FIGS. 4 and 5, the display panel DP may include a first conductive pattern CP1, a second conductive pattern CP2, and at least one groove pattern GR1 and GR2, which are disposed at (e.g., in or on) the hole area HA. FIG. 4 shows a shape of a first groove pattern GR1 when viewed in a plane (e.g., in a plan view), and FIG. 5 shows a cross-section of the first groove pattern GR1 and a second groove pattern GR2.

Referring to FIG. 5, the display panel DP may include the base substrate SUB, a circuit element layer DP-CL, and a display element layer DP-OL. The circuit element layer DP-CL and the display element layer DP-OL may be sequentially stacked on the base substrate SUB.

The base substrate SUB may include a glass substrate, a metal substrate, a polymer substrate, or an organic/inorganic composite material substrate. The base substrate SUB may include a synthetic resin layer. As an example, the synthetic resin layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyimide-based resin, a perylene-based resin, or a polyimide-based resin. However, the materials for the base substrate SUB are not limited thereto or thereby.

The circuit element layer DP-CL may include a thin film transistor TR (hereinafter, referred to as a transistor TR), and a plurality of insulating layers 10, 20, 30, 40, and 50, which are disposed on the base substrate SUB. FIG. 5 shows the circuit element layer DP-CL including first, second, third, fourth, and fifth insulating layers 10, 20, 30, 40, and 50. The circuit element layer DP-CL may include signal lines connected to the pixels PX.

The circuit element layer DP-CL may include a conductive pattern and a semiconductor pattern, which are disposed between the insulating layers 10, 20, 30, 40, and 50. The conductive pattern and the semiconductor pattern may form the transistor TR, electrodes, and signal lines connected to the transistor TR. An insulating layer, a semiconductor layer, and a conductive layer may be formed on the base substrate SUB by a coating or a depositing process, and the insulating layer, the semiconductor layer, and the conductive layer may be selectively patterned through several photolithography processes. After the processes are completed, the semiconductor pattern and the conductive pattern included in the circuit element layer DP-CL may be formed.

The first insulating layer 10 may be disposed on the base substrate SUB. The first insulating layer 10 may be provided as a barrier layer and/or a buffer layer. The first insulating layer 10 may prevent or substantially prevent foreign substances from entering the transistor TR from the outside, or may improve an adhesion between the base substrate SUB and the semiconductor pattern SP of the transistor TR.

The first insulating layer 10 may include an inorganic layer. As an example, the first insulating layer 10 may include at least one of a silicon oxide layer or a silicon nitride layer. According to an embodiment, the first insulating layer 10 may include one or more silicon oxide layers, and one or more silicon nitride layers that are alternately stacked with the silicon oxide layers.

The second to fifth insulating layers 20 to 50 may be sequentially stacked on the base substrate SUB. The second to fifth insulating layers 20 to 50 may include an inorganic layer or an organic layer. As an example, the inorganic layer may include at least one of aluminum oxide, titanium oxide, silicon oxide, silicon nitride, silicon oxynitride, zirconium oxide, or hafnium oxide. The organic layer may include a phenolic-based polymer, an acrylic-based polymer, an imide-based polymer, an aryl ether-based polymer, an amide-based polymer, a fluorine-based polymer, a p-xylene-based polymer, a vinyl alcohol-based polymer, or suitable blends thereof. However, the materials for the second to fifth insulating layers 20 to 50 are not limited thereto or thereby.

The transistor TR may be disposed on the first insulating layer 10. The transistor TR may include the semiconductor pattern SP and a gate electrode GE.

The semiconductor pattern SP may be disposed on the first insulating layer 10. The semiconductor pattern SP may include a silicon semiconductor, such as a crystalline silicon semiconductor, a polysilicon semiconductor, or an amorphous silicon semiconductor, but the present disclosure is not limited thereto or thereby. The semiconductor pattern SP may include an oxide semiconductor. The semiconductor pattern SP may include various suitable materials, as long as the semiconductor pattern SP has a semiconductor property, and thus, the material of the semiconductor pattern SP is not particularly limited.

The semiconductor pattern SP may include a source area Sa, a drain area Da, and a channel area Ca. The semiconductor pattern SP may include a plurality of areas distinguished from each other depending on a conductivity thereof. As an example, the semiconductor pattern SP may have different electrical properties depending on whether or not it is doped, whether it is doped with an N-type dopant or a P-type dopant, or whether a metal oxide is reduced. A portion of the semiconductor pattern, which has a relatively high conductivity, may serve as an electrode or a signal line, and may correspond to the source area Sa and the drain area Da of the transistor TR. A non-doped or non-reduced portion having a relatively low conductivity may correspond to the channel area Ca (e.g., an active area) of the transistor TR.

The second insulating layer 20 may be disposed on the first insulating layer 10, and may cover the semiconductor pattern SP of the transistor TR. The second insulating layer 20 may include an inorganic layer having a single-layer structure or a multiple-layered structure.

The gate electrode GE may be disposed on the second insulating layer 20. The gate electrode GE may overlap with the channel area Ca when viewed in a plane (e.g., in a plan view). The gate electrode GE may serve as a mask in a process of doping the semiconductor pattern SP.

The third insulating layer 30 may be disposed on the second insulating layer 20, and may cover the gate electrode GE. The third insulating layer 30 may include an inorganic layer having a single-layer structure or a multiple-layered structure, but the present disclosure is not limited thereto or thereby.

A source electrode SE and a drain electrode DE may be disposed on the third insulating layer 30. The source electrode SE may be connected to the source area Sa of the semiconductor pattern SP via a contact hole defined (e.g., penetrating) through the second and third insulating layers 20 and 30. The drain electrode DE may be connected to the drain area Da of the semiconductor pattern SP via a contact hole defined (e.g., penetrating) through the second and third insulating layers 20 and 30. The source electrode SE and the drain electrode DE may be disposed to be spaced apart from each other on the third insulating layer 30.

The fourth insulating layer 40 may be disposed on the third insulating layer 30, and may cover the source electrode SE and the drain electrode DE. The fourth insulating layer 40 may include an organic layer. The fourth insulating layer 40 including the organic layer may cover a step difference between components disposed thereunder, and may provide a flat or substantially flat surface.

A connection electrode CNE may be disposed on the fourth insulating layer 40. The connection electrode CNE may electrically connect the transistor TR and the light emitting element OL to each other. The connection electrode CNE may be connected to the drain electrode DE via a contact hole defined (e.g., penetrating) through the fourth insulating layer 40.

The fifth insulating layer 50 may be disposed on the fourth insulating layer 40, and may cover the connection electrode CNE. The fifth insulating layer 50 may include an organic layer. The fifth insulating layer 50 including the organic layer may provide a flat or substantially flat surface.

However, a configuration of the circuit element layer DP-CL is not limited to that shown in FIG. 5, and the circuit element layer DP-CL may further include an insulating layer. At least one or more insulating layers may be provided to be disposed between the first to fifth insulating layers 10 to 50, to be additionally disposed under (e.g., underneath) the first insulating layer 10, or to be disposed on the fifth insulating layer 50. The circuit element layer DP-CL may have various suitable cross-sectional structures according to a circuit design, and thus, is not particularly limited.

The display element layer DP-OL may be disposed on the circuit element layer DP-CL. The display element layer DP-OL may include the light emitting element OL, a pixel definition layer PDL, and an encapsulation layer TFE.

The light emitting element OL may be disposed at (e.g., in or on) the display area DA. The light emitting element OL may include the pixel electrode AE, a light emitting layer EML, and a common electrode CE. In some embodiments, the light emitting element OL may further include a hole control layer HCL (e.g., refer to FIG. 6A) disposed between the pixel electrode AE and the light emitting layer EML, and an electron control layer ECL disposed between the light emitting layer EML and the common electrode CE.

The pixel electrode AE may be an anode electrode, and the common electrode CE may be a cathode electrode. As an example, the light emitting element OL may include an organic light emitting element, a quantum dot light emitting element, a micro-LED light emitting element, or a nano-LED light emitting element, but the present disclosure is not limited thereto or thereby. According to an embodiment, the light emitting element OL may include various suitable structures, as long as light may be generated or an amount of the light may be controlled according to an electrical signal.

The pixel electrode AE may be disposed on the fifth insulating layer 50. The pixel electrode AE may be connected to the connection electrode CNE via a contact hole defined (e.g., penetrating) through the fifth insulating layer 50. The pixel electrode AE may be electrically connected to the drain area Da of the transistor TR via the connection electrode CNE and the drain electrode DE.

The pixel definition layer PDL may be disposed on the fifth insulating layer 50. The pixel definition layer PDL be provided with a light emitting opening OP-PX defined (e.g., penetrating) therethrough to expose at least a portion of the pixel electrode AE. The portion of the pixel electrode AE, which is exposed through the light emitting opening OP-PX, may correspond to the light emitting area.

The pixel definition layer PDL may be formed of a polymer resin. As an example, the pixel definition layer PDL may include a polyacrylate-based resin or a polyimide-based resin. The pixel definition layer PDL may further include an inorganic material, in addition to the polymer resin. According to an embodiment, the pixel definition layer PDL may include an inorganic material. As an example, the pixel definition layer PDL may include silicon nitride (SiNₓ), silicon oxide (SiOₓ), or silicon oxynitride (SiOₓN_{y}).

The pixel definition layer PDL may include a light absorbing material. The pixel definition layer PDL may include a black coloring agent. The black coloring agent may include a black pigment or a black dye. The black coloring agent may include a metal material, such as carbon black, chrome, and/or the like, or an oxide thereof. However, the pixel definition layer PDL is not limited thereto or thereby.

The light emitting layer EML may be disposed on the pixel electrode AE. The light emitting layer EML may be disposed in an area corresponding to the light emitting opening OP-PX. In other words, the light emitting layer EML may be provided for each of the pixels PX (e.g., refer to FIG. 3), and the light emitting layer EML of the pixels PX may be provided in the form of a light emitting pattern that is separately provided in each pixel when viewed in a plane (e.g., in a plan view). However, the present disclosure is not limited thereto or thereby.

The light emitting layer EML may provide light with a suitable color. The light emitting layer EML may emit light having at least one of a red color, a blue color, or a green color, but the present disclosure is not limited thereto or thereby. The light emitting layer EML may generate white light by a combination of light emitting materials that generate the red color, the green color, and the blue color, respectively.

The light emitting layer EML may include an organic light emitting material and/or an inorganic light emitting material. As an example, the light emitting layer EML may include a fluorescent or phosphorescent material, an organometallic complex light emitting material, or a quantum dot. The light emitting layer EML may have a multi-layered structure. As an example, the light emitting layer EML may include a main light emitting layer, and an auxiliary light emitting layer disposed on the main light emitting layer. The main light emitting layer and the auxiliary light emitting layer may have a different thickness from each other depending on a wavelength of the light emitted from the light emitting layer EML, and a resonant distance of the light emitting element OL may be controlled by providing the auxiliary light emitting layer. In addition, when the auxiliary light emitting layer is provided, a color purity of light emitted from the light emitting layer EML may be improved.

The common electrode CE may be disposed on the light emitting layer EML. The common electrode CE may be commonly disposed over the pixels PX to receive a common voltage. The common electrode CE may extend from the display area DA, and may be disposed to overlap with the hole area HA. The common electrode CE may be disconnected at (e.g., in or on) the hole area HA by the groove patterns GR1 and GR2.

A voltage may be applied to the pixel electrode AE via the transistor TR, and the common voltage may be applied to the common electrode CE via a signal line for applying the common voltage. Holes and electrons, which are injected into the light emitting layer EML, may be recombined with each other to generate excitons, and the light emitting element OL may emit light through the display area DA when the excitons return to a ground state from an excited state.

Each of the pixel electrode AE and the common electrode CE may be a transmissive electrode, a transflective electrode, or a reflective electrode. The transmissive electrode may include a transparent metal oxide, such as, indium tin oxide (ITO), indium zinc oxide (IZO), zinc oxide (ZnO), indium tin zinc oxide (ITZO), and/or the like. The transflective electrode or the reflective electrode may include Ag, Mg, Cu, Al, Pt, Pd, Au, Ni, Nd, Ir, Cr, Li, Ca, LiF/Ca (e.g., a stacked structure of LiF and Ca), LiF/Al (e.g., a stacked structure of LiF and Al), Mo, Ti, Yb, W, a suitable compound thereof, or a suitable mixture thereof (e.g., AgMg, AgYb, or MgYb).

Each of the pixel electrode AE and the common electrode CE may have a multi-layered structure of the reflective layer or the semi-transmissive layer, which is formed of one or more of the above-mentioned materials, and a transparent conductive layer formed of indium tin oxide (ITO), indium zinc oxide (IZO), zinc oxide (ZnO), or indium tin zinc oxide (ITZO). As an example, the pixel electrode AE and the common electrode CE may have a three-layered structure of ITO/Ag/ITO, but the present disclosure is not limited thereto or thereby.

The encapsulation layer TFE may be disposed on the light emitting element OL, and may encapsulate the light emitting element OL. The encapsulation layer TFE may include at least one insulating layer. The encapsulation layer TFE may include a plurality of inorganic layers IOL1 and IOL2, and at least one organic layer MN disposed between the inorganic layers IOL1 and IOL2. A first inorganic layer IOL1 may be disposed on the common electrode CE. The organic layer MN and a second inorganic layer IOL2 may be sequentially disposed on the first inorganic layer IOL1.

The first inorganic layer IOL1 and the second inorganic layer IOL2 may protect the light emitting element OL from moisture and/or oxygen. The first inorganic layer IOL1 and the second inorganic layer IOL2 may include at least one of aluminum oxide, titanium oxide, silicon oxide, silicon nitride, silicon oxynitride, zirconium oxide, or hafnium oxide, but the materials of the first and second inorganic layers IOL1 and IOL2 are not limited thereto or thereby.

The organic layer MN may protect the light emitting layer OL from foreign substances, such as dust particles. The organic layer MN may include an acrylic-based organic layer, but is not limited thereto or thereby.

Referring to FIGS. 4 and 5, the hole area HA may be surrounded (e.g., around a periphery thereof) by the display area DA. The pixels PX may be arranged at (e.g., in or on) the display area DA, and the pixels PX may not be arranged at (e.g., in or on) the hole area HA. The signal line electrically connected to the pixels PX, which are spaced apart from each other with the hole area HA interposed therebetween, may be disposed at (e.g., in or on) the hole area HA.

The hole HH may be defined in the hole area HA. FIG. 4 shows a structure in which one hole HH is defined in the hole area HA as a representative example, but the number of the holes HH is not limited thereto or thereby. According to an embodiment, the hole HH may be provided in a plurality in one or more hole areas HA. According to an embodiment, the hole area HA may be provided in a plurality, and may be arranged to be spaced apart from each other at (e.g., in or on) the display area DA. One or more holes HH may be defined in each of the plurality of hole areas HA.

The hole HH may have a circular shape when viewed in the plane (e.g., in a plan view), but the shape of the hole HH is not limited thereto or thereby. The hole HH may have various suitable shapes, such as a polygonal shape or an irregular shape.

The hole HH may be a through hole penetrating through the display panel DP. Referring to FIG. 5, the hole HH may be formed to penetrate from an upper surface of the display element layer DP-OL to a rear surface of the base substrate SUB.

The groove pattern GR1 and GR2 may be provided in a plurality, and the groove patterns GR1 and GR2 may be disposed at (e.g., in or on) the hole area HA. The number of the groove patterns GR1 and GR2 disposed at (e.g., in or on) the hole area HA of the display panel DP is not limited to that shown in FIG. 5.

The first and second groove patterns GR1 and GR2 may be disposed to be spaced apart from each other. The first and second groove patterns GR1 and GR2 may be sequentially arranged in a direction toward the display area DA from the hole HH when viewed in the plane (e.g., in a plan view). In other words, the first groove pattern GR1 may be disposed to be closer to the hole HH than the second groove pattern GR2.

The first groove pattern GR1 may surround (e.g., around a periphery of) the hole HH when viewed in the plane (e.g., in a plan view). The second groove pattern GR2 may surround (e.g., around peripheries of) the hole HH and the first groove pattern GR1 when viewed in the plane (e.g., in a plan view). The first and second groove patterns GR1 and GR2 may have a closed line shape surrounding (e.g., around a periphery of) the hole HH. As an example, the hole HH may have a circular shape when viewed in the plane (e.g., in a plan view), and each of the first and second groove patterns GR1 and GR2 may have a circular ring shape when viewed in the plane (e.g., in a plan view). However, the shape of the first and second groove patterns GR1 and GR2 is not particularly limited, as long as the first and second groove patterns GR1 and GR2 are defined to surround (e.g., around a periphery of) the hole HH.

The first and second groove patterns GR1 and GR2 may be formed by removing a portion of some of the components of the display panel DP to be recessed from the upper surface of the display panel DP. The first and second groove patterns GR1 and GR2 may be formed by being recessed in at least one insulating layer included in the display panel DP along a thickness direction that is parallel to or substantially parallel to the third direction DR3. Accordingly, unlike the hole HH, the first and second groove patterns GR1 and GR2 may not penetrate through an entire thickness of the display panel DP. Accordingly, the first and second groove patterns GR1 and GR2 may not be opened to the rear surface of the base substrate SUB.

Still referring to FIG. 5, the first and second groove patterns GR1 and GR2 may be formed through the fourth insulating layer 40. A portion of an upper surface of the third insulating layer 30 may be exposed through the first and second groove patterns GR1 and GR2. The fourth insulating layer 40, through which the first and second groove patterns GR1 and GR2 are formed, may include an organic layer, and the third insulating layer 30 exposed through the first and second groove patterns GR1 and GR2 may include an inorganic layer, but the present disclosure is not limited thereto or thereby. According to an embodiment, the first and second groove patterns GR1 and GR2 may be formed by recessing a portion of the fourth insulating layer 40 from an upper surface of the fourth insulating layer 40 toward the third insulating layer 30.

However, the present disclosure is not limited thereto, and the first and second groove patterns GR1 and GR2 may be formed at various suitable positions on the third insulating layer 30. The first and second groove patterns GR1 and GR2 may be formed in an insulating layer disposed under (e.g., underneath) the first conductive pattern CP1. In other words, in a case where a position of the first conductive pattern CP1 is modified according to a design change of the circuit element layer DP-CL, the first and second groove patterns GR1 and GR2 may be formed in another insulating layer, rather than in the fourth insulating layer 40, and the present disclosure is not particularly limited.

The organic layer MN of the encapsulation layer TFE may extend from the display area DA to the hole area HA, and at least one of the first and second groove patterns GR1 and GR2 may overlap with the organic layer MN of the encapsulation layer TFE. As an example, the second groove pattern GR2, which is disposed relatively closer to the display area DA from among the first and second groove patterns GR1 and GR2, may be filled with the organic layer MN.

The second groove pattern GR2 filled with the organic layer MN may have a durability that is relatively improved compared to that of the first groove pattern GR1. The organic layer MN may cover a tip portion TP disposed on (e.g., protruding over) the second groove pattern GR2. As the organic layer MN covers the tip portion TP, the tip portion TP, which may be relatively vulnerable to impacts due to its protruding shape, may be prevented or substantially prevented from being damaged, and the reliability and durability of the display panel DP may be improved.

At least one of the first and second groove patterns GR1 and GR2 may be spaced apart from the organic layer MN. As an example, the first groove pattern GR1, which is disposed relatively closer to the hole HH from among the first and second groove patterns GR1 and GR2, may be spaced apart from the organic layer MN.

The organic layer MN may be formed by curing a liquid organic resin, and the groove patterns GR1 and GR2 may prevent or substantially prevent the liquid organic resin from flowing over the hole area HA. In other words, the groove patterns GR1 and GR2 may block a continuity of the organic layer MN within the hole area HA. Accordingly, as the continuity of the organic layer MN is blocked, a path through which external contaminants, which may be infiltrated into the hole area HA, that may enter the display area DA may be easily blocked.

The organic layer MN may be formed to be spaced apart from the hole HH by the groove patterns GR1 and GR2. Accordingly, a cross-section of the organic layer MN may not be exposed through the hole HH, and moisture and/or oxygen may be prevented or substantially prevented from entering the organic layer MN through the hole HH, and from moving to the organic layer MN and the light emitting element OL, which are disposed at (e.g., in or on) the display area DA. Thus, the reliability of the display panel DP may be improved.

The inorganic layers IOL1 and IOL2 of the encapsulation layer TFE may extend from the display area DA to the hole area HA, and at least one of the inorganic layers from among the inorganic layers IOL1 and IOL2 may cover an inner surface of the first and second groove patterns GR1 and GR2.

For example, as shown in FIG. 5, the first inorganic layer IOL1 may extend to the hole area HA, and may be in contact with the inner surface of the first and second groove patterns GR1 and GR2. The organic layer MN may cover the first inorganic layer IOL1 disposed on the inner surface of the second groove pattern GR2. The first inorganic layer IOL1 disposed on the inner surface of the first groove pattern GR1 may be spaced apart from the organic layer MN. Accordingly, the second inorganic layer IOL2 may be in contact with the first inorganic layer IOL1 disposed on the inner surface of the first groove pattern GR1. As the inner surfaces of the first and second groove patterns GR1 and GR2 are covered by the first inorganic layer IOL1, moisture and/or oxygen may be prevented or substantially prevented from entering through the groove patterns GR1 and GR2.

FIG. 6A is an enlarged cross-sectional view showing the first groove pattern GR1 in more detail. A lower insulating layer INS shown in FIG. 6A may correspond to the insulating layers and the base substrate SUB that are disposed under (e.g., underneath) the insulating layer (e.g., the fourth insulating layer 40) through which the groove patterns GR1 and GR2 are defined. For example, referring to FIG. 5, the lower insulating layer INS may include the base substrate SUB, and the first, second, and third insulating layers 10, 20, and 30. For convenience of illustration, FIG. 6A shows the third insulating layer 30 as an uppermost layer of the lower insulating layer INS.

Referring to FIG. 6A, the inner surface of the first groove pattern GR1 may include an inner bottom surface BS, and an inner side surface SS inclined with respect to the inner bottom surface BS. In FIG. 6A, the inner side surface SS is shown as being vertical to the inner bottom surface BS, but an angle between the inner bottom surface BS and the inner side surface SS is not limited thereto or thereby.

The inner side surface SS may be defined by an inner side surface of the fourth insulating layer 40 that is exposed when a portion of the fourth insulating layer 40 is penetrated and removed. The inner bottom surface BS may be defined as a portion of the upper surface of the third insulating layer 30 that is exposed without being covered by the fourth insulating layer 40. The inner side surface of the fourth insulating layer 40 may correspond to a side surface of the organic layer, and the upper surface of the third insulating layer 30 that is exposed without being covered by the fourth insulating layer 40 may correspond to an upper surface of the inorganic layer, but the present disclosure is not limited thereto or thereby. According to an embodiment, the inner bottom surface BS and the inner side surface SS may be formed by recessing a portion of the fourth insulating layer 40, and may be provided integrally with each other.

The first inorganic layer IOL1 may cover the inner bottom surface BS and the inner side surface SS, which define the first groove pattern GR1. The first inorganic layer IOL1 may be in contact with the inner bottom surface BS and the inner side surface SS.

The first inorganic layer IOL1 may maintain or substantially maintain a shape of the first groove pattern GR1, and may cover the first groove pattern GR1. The first groove pattern GR1 may have a shape that is recessed from the upper surface of the fourth insulating layer 40, and the first inorganic layer IOL1 may be disposed in the first groove pattern GR1 to correspond to the shape of the first groove pattern GR1. Accordingly, an upper surface of the first inorganic layer IOL1, which overlaps with the first groove pattern GR1, may have a recessed shape. While the first groove pattern GR1 has been described in more detail above, the above-description of the first groove pattern GR1 may be applied to the second groove pattern GR2 (e.g., refer to FIG. 5) in the same or substantially the same (or similar) manner, and thus, redundant description thereof may not be repeated.

The second inorganic layer IOL2 may be in contact with the first inorganic layer IOL1 in an area in which the organic layer MN of the encapsulation layer TFE is not disposed, and may encapsulate the organic layer MN. Accordingly, the first inorganic layer IOL1 and the second inorganic layer IOL2 may prevent or substantially prevent moisture and/or oxygen from entering the organic layer MN.

The second inorganic layer IOL2 may be in contact with the first inorganic layer IOL1 disposed in the first groove pattern GR1. The second inorganic layer IOL2 may be disposed in the first groove pattern GR1 to correspond to the shape of the first groove pattern GR1 and the first inorganic layer IOL1. Accordingly, an upper surface of the second inorganic layer IOL2 overlapping with the first groove pattern GR1 may have the recessed shape.

Referring again to FIGS. 4 and 5, the first conductive pattern CP1 and the second conductive pattern CP2 may be disposed at (e.g., in or on) the hole area HA, and may be spaced apart from the pixels PX. The first conductive pattern CP1 and the second conductive pattern CP2 may be electrically insulated from the pixels PX. The first conductive pattern CP1 and the second conductive pattern CP2 may surround (e.g., around a periphery of) the hole HH when viewed in the plane (e.g., in a plan view).

The first conductive pattern CP1 may be disposed on the insulating layer in which the groove patterns GR1 and GR2 are formed. Referring to FIG. 5, the first conductive pattern CP1 may be disposed on the fourth insulating layer 40. The first conductive pattern CP1 may include a plurality of first pattern portions PA1-1, PA1-2, and PA1-3.

The first pattern portions PA1-1, PA1-2, and PA1-3 may be disposed at (e.g., in or on) the same layer as each other, and may be spaced apart from each other when viewed in the plane (e.g., in a plan view). The first pattern portions PA1-1, PA1-2, and PA1-3 may be disposed at (e.g., in or on) the hole area HA between the hole HH and the display area DA. The first pattern portions PA1-1, PA1-2, and PA1-3 may be arranged to be spaced apart from each other along a direction away from a center of the hole HH when viewed in the plane (e.g., in a plan view). From among the first pattern portions PA1-1, PA1-2, and PA1-3, the first pattern portions that are adjacent to each other may be spaced apart from each other with a groove pattern interposed therebetween when viewed in the plane (e.g., in a plan view).

Each of the first pattern portions PA1-1, PA1-2, and PA1-3 may surround (e.g., around a periphery of) the hole HH when viewed in the plane (e.g., in a plan view). Each of the first pattern portions PA1-1, PA1-2, and PA1-3 may have a closed line shape when viewed in the plane (e.g., in a plan view). FIG. 4 shows two of the first pattern portions PA1-1 and PA1-2, each having a circular ring shape as a representative example, but the shape of each of the first pattern portions PA1-1, PA1-2, and PA1-3 is not limited thereto or thereby.

From among the first pattern portions PA1-1, PA1-2, and PA1-3, an inner side surface of the first pattern portion PA1-1 closest to the hole HH may define the hole HH. Spaces between the first pattern portions PA1-1, PA1-2, and PA1-3 that are adjacent to each other may define first pattern holes HO1, respectively.

The first conductive pattern CP1 may be disposed at (e.g., in or on) the same layer as that of the connection electrode CNE of the circuit element layer DP-CL. The first conductive pattern CP1 may be formed together with the connection electrode CNE through the same process. Accordingly, the first conductive pattern CP1 may be formed without using a separate additional process.

The first conductive pattern CP1 may include a conductive material. As an example, the first conductive pattern CP1 may include a metal material. The first conductive pattern CP1 may include the same material as that of the connection electrode CNE. The material included in the connection electrode CNE may be a conductive material having a relatively low electrical resistance, and thus, similarly, the first conductive pattern CP1 may include a conductive material having a low electrical resistance.

Each of the first pattern portions PA1-1, PA1-2, and PA1-3 of the first conductive pattern CP1 may have the same or substantially the same structure as that of the connection electrode CNE. As an example, referring to FIG. 6A, each of the first pattern portions PA1-1, PA1-2, and PA1-3 may include a plurality of conductive layers M1, M2, and M3. The conductive layers M1, M2, and M3 may include first, second, and third conductive layers M1, M2, and M3 that are sequentially stacked in the third direction DR3.

The first conductive layer M1 may include a material different from that of the second conductive layer M2. The first conductive layer M1 may include the same or substantially the same material as that of the third conductive layer M3, but the present disclosure is not limited thereto or thereby.

Each of the first conductive layer M1 and the third conductive layer M3 may include a metal material having a corrosion resistance. The first conductive layer M1 and the third conductive layer M3 may be disposed on a lower surface and an upper surface, respectively, of the second conductive layer M2, and may protect the second conductive layer M2 from scratches generated in subsequent processes. In addition, the first conductive layer M1 and the third conductive layer M3 may prevent or substantially prevent the second conductive layer M2 from corroding due to moisture. As an example, the first conductive layer M1 and the third conductive layer M3 may include at least one of molybdenum, titanium, or a suitable alloy thereof. However, the materials for the first conductive layer M1 and the third conductive layer M3 are not limited thereto or thereby.

The second conductive layer M2 may be disposed on the first conductive layer M1. The second conductive layer M2 may include a metal material having a low resistance. As an example, the second conductive layer M2 may include at least one of gold, silver, copper, aluminum, platinum, or suitable alloys thereof. However, the material for the second conductive layer M2 is not limited thereto or thereby.

The second conductive layer M2 may have a thickness greater than a thickness of each of the first conductive layer M1 and the third conductive layer M3. The connection electrode CNE, which has the same or substantially the same structure as that of the first conductive pattern CP1, may include a conductive layer including the same material as that of the second conductive layer M2, and having the same thickness as that of the second conductive layer M2. As the conductive layer having the relatively low resistance may have a relatively greater thickness, the connection electrode CNE may have a relatively low resistance.

The first pattern holes HO1 may overlap with the groove patterns GR1 and GR2, respectively. From among the first pattern portions PA1-1, PA1-2, and PA1-3, two first pattern portions that are disposed adjacent to each other may define one first pattern hole HO1. When the groove patterns GR1 and GR2 are provided at (e.g., in or on) the hole area HA, the first pattern holes HO1 corresponding to the groove patterns GR1 and GR2 may be defined through the first conductive pattern CP1. Accordingly, each of the first pattern holes HO1 may overlap with a corresponding groove pattern from among the groove patterns GR1 and GR2.

Referring to FIGS. 5 and 6A, each of the first pattern portions PA1-1, PA1-2, and PA1-3 may include the tip portion TP defining the first pattern hole HO1. In other words, a side surface S-1 of the tip portion TP may define the first pattern hole HO1. From among the first pattern portions PA1-1, PA1-2, and PA1-3, side surfaces S-1 of the tip portions TP of the first pattern portions that are adjacent to each other may face each other in the first direction DR1. One first pattern hole HO1 may be defined by the tip portions TP that protrude towards each other in the first direction DR1.

The side surfaces S-1 of the tip portions TP may protrude more than the inner side surfaces SS of the groove patterns GR1 and GR2 in the first direction DR1. Accordingly, the tip portion TP may have a length D-T in the first direction DR1. The length D-T of the tip portion TP may be defined as a protruding length of the tip portion TP from the inner side surface SS of a corresponding groove pattern GR1 and GR2 in a direction toward a center of the corresponding groove pattern GR1 and GR2 when viewed in the plane (e.g., in a plan view).

The fifth insulating layer 50 may be disposed on the first conductive pattern CP1. The fifth insulating layer 50 may be provided with a first opening OP-1 overlapping with the first pattern hole HO1 and the corresponding groove pattern GR1 and GR2. In a case where the first pattern hole HO1 is provided in a plurality, the fifth insulating layer 50 may be provided with a plurality of first openings OP-1 defined (e.g., penetrating) therethrough to correspond to the first pattern holes HO1, respectively. Each of the first openings OP-1 may overlap with a corresponding groove pattern from among the groove patterns GR1 and GR2.

The first opening OP1 may have a width greater than a width of the first pattern hole HO1 in the first direction DR1. Accordingly, the tip portions TP of the first conductive pattern CP1 and the first pattern hole HO1 between the tip portions TP may be exposed through the first opening OP-1.

The light emitting element OL may include the hole control layer HCL and the electron control layer ECL as shown in FIG. 6A. The hole control layer HCL may include at least one of a hole transport layer or a hole injection layer, and the electron control layer ECL may include at least one of an electron transport layer or an electron injection layer. FIG. 6A shows a structure in which the hole control layer HCL and the electron control layer ECL are disposed at (e.g., in or on) the hole area HA as a representative example. The hole control layer HCL and the electron control layer ECL may be commonly disposed over the pixels PX. In other words, each of the hole control layer HCL and the electron control layer ECL may be provided as a common layer, like that of the common electrode CE.

The hole control layer HCL may be disposed on the pixel electrode AE and the pixel definition layer PDL, and may extend from the display area DA to the hole area HA. The electron control layer ECL may be disposed on the light emitting layer EML, and may extend from the display area DA to the hole area HA. Accordingly, each of the hole control layer HCL and the electron control layer ECL may be disposed in areas adjacent to the groove patterns GR1 and GR2.

The hole control layer HCL, the electron control layer ECL, and the common electrode CE, which are provided as the common layers, may cover a side surface of the fifth insulating layer 50, which is exposed through the first opening OP-1 defined (e.g., penetrating) through the fifth insulating layer 50. The hole control layer HCL, the electron control layer ECL, and the common electrode CE may be disposed on the tip portion TP. However, the structure of the layers provided as the common layers is not limited thereto or thereby.

The second conductive pattern CP2 may be disposed on the fifth insulating layer 50. The second conductive pattern CP2 may include a plurality of second pattern portions PA2-1, PA2-2, PA2-3, and PA2-4.

The second pattern portions PA2-1, PA2-2, PA2-3, and PA2-4 may be disposed at (e.g., in or on) the same layer as each other, and may be spaced apart from each other. The second pattern portions PA2-1, PA2-2, PA2-3, and PA2-4 may be disposed at (e.g., in or on) the hole area HA between the hole HH and the display area DA. The second pattern portions PA2-1, PA2-2, PA2-3, and PA2-4 may be arranged to be spaced apart from each other in a direction away from the center of the hole HH when viewed in the plane (e.g., in a plan view). The second pattern portions PA2-1, PA2-2, PA2-3, and PA2-4 may overlap with the first conductive pattern CP1 when viewed in the plane (e.g., in a plan view).

Each of the second pattern portions PA2-1, PA2-2, PA2-3, and PA2-4 may surround (e.g., around a periphery of) the hole HH when viewed in the plane (e.g., in a plan view). Each of the second pattern portions PA2-1, PA2-2, PA2-3, and PA2-4 may have a closed line shape when viewed in the plane (e.g., in a plan view). FIG. 4 shows two of the second pattern portions PA2-1 and PA2-2, each having a circular ring shape as a representative example, but the shape of the second pattern portions PA2-1, PA2-2, PA2-3, and PA2-4 is not limited thereto or thereby.

From among the second pattern portions PA2-1, PA2-2, PA2-3, and PA2-4, an inner side surface of the second pattern portion PA2-1 closest to the hole HH may define a through hole overlapping with the hole HH, and having a size greater than that of the hole HH in the plane (e.g., in a plan view), but the present disclosure is not limited thereto or thereby. According to an embodiment, an inner side surface of the second pattern portion PA2-1 closest to the hole HH from among the second pattern portions PA2-1, PA2-2, PA2-3, and PA2-4 may define the hole HH. Spaces between the second pattern portions PA2-1, PA2-2, PA2-3, and PA2-4 that are adjacent to each other may define second pattern holes HO2, respectively.

The second conductive pattern CP2 may include the same material as that of the pixel electrode AE. The second conductive pattern CP2 may include a conductive material. As an example, the second conductive pattern CP2 may include a metal material. The second conductive pattern CP2 may have the same or substantially the same structure as that of the pixel electrode AE. As an example, when the pixel electrode AE has a three-layered structure of ITO/Ag/ITO, the second conductive pattern CP2 may also have the three-layered structure of ITO/Ag/ITO.

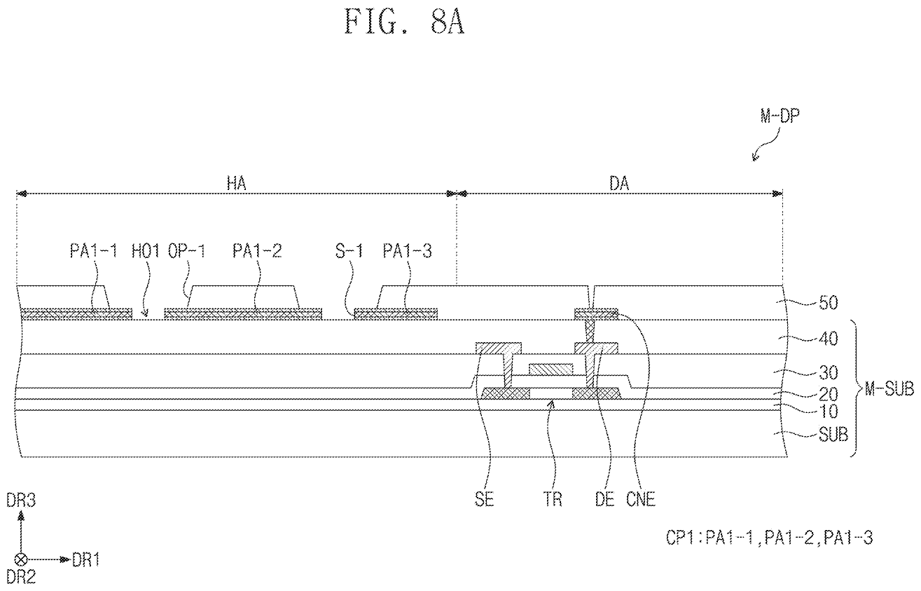

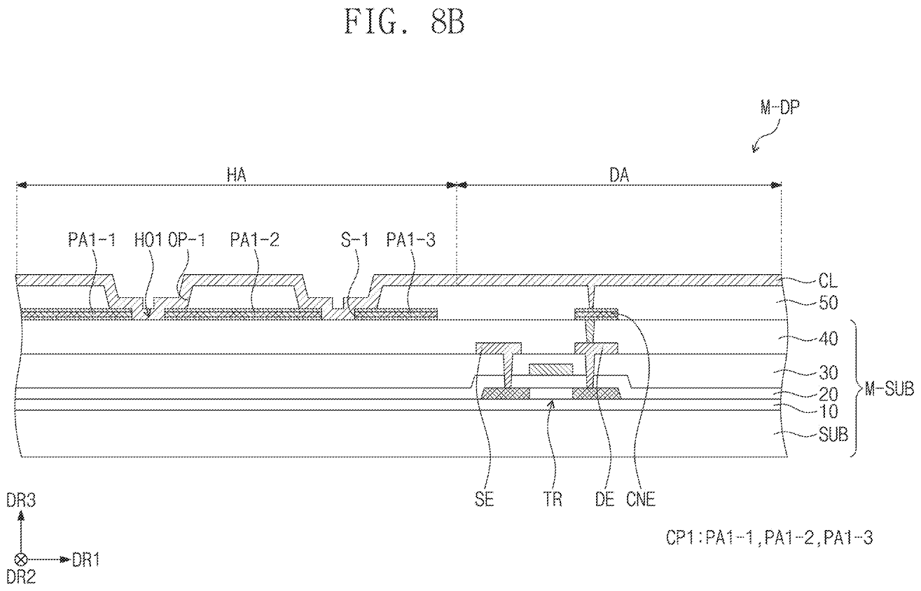

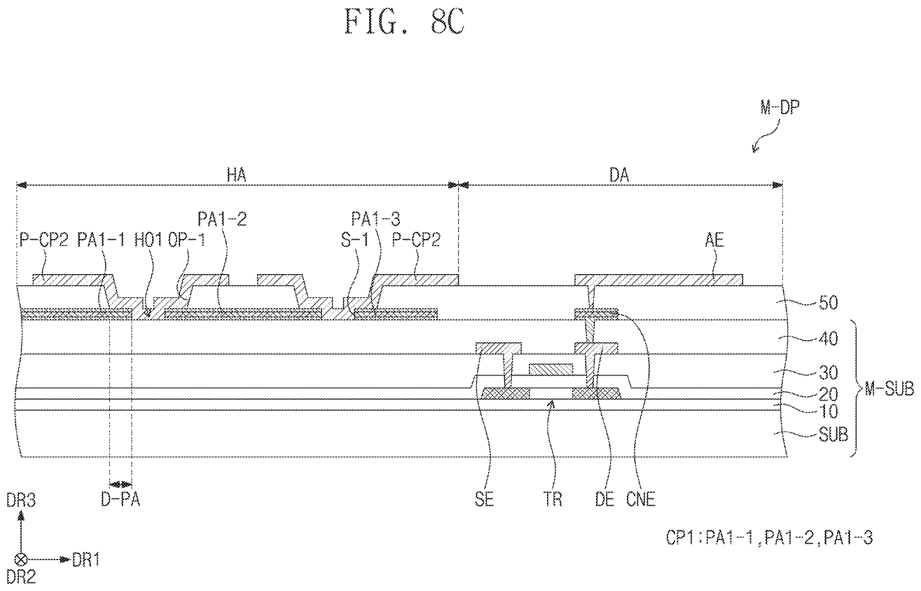

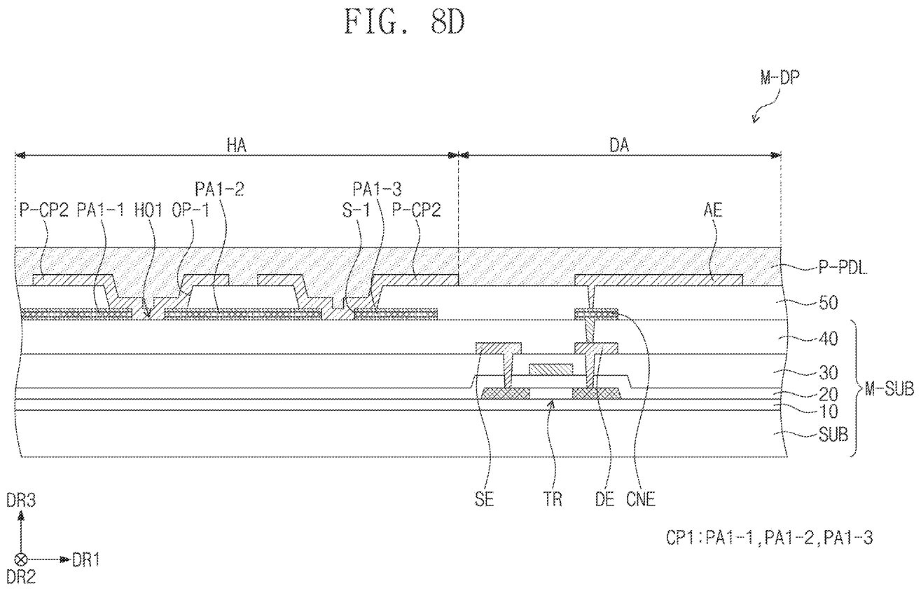

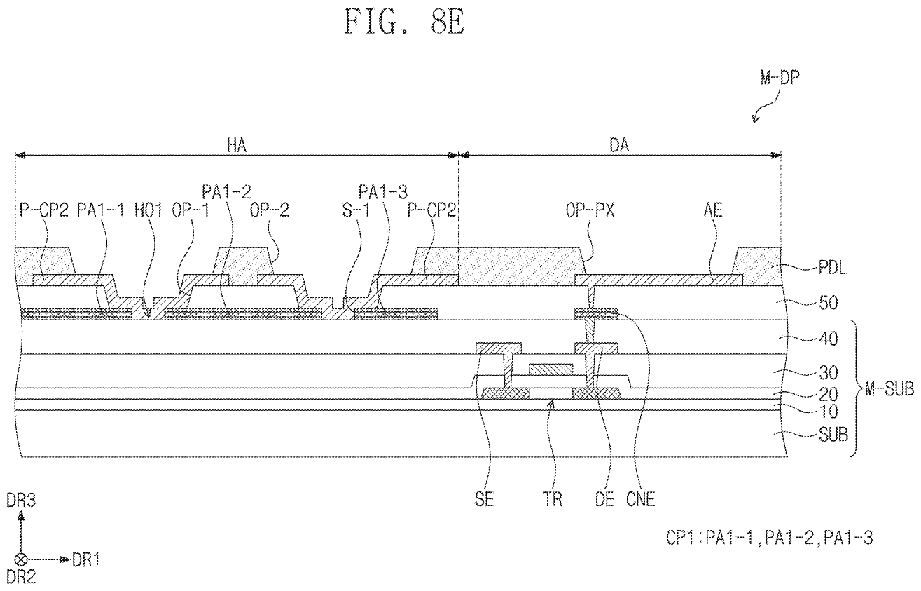

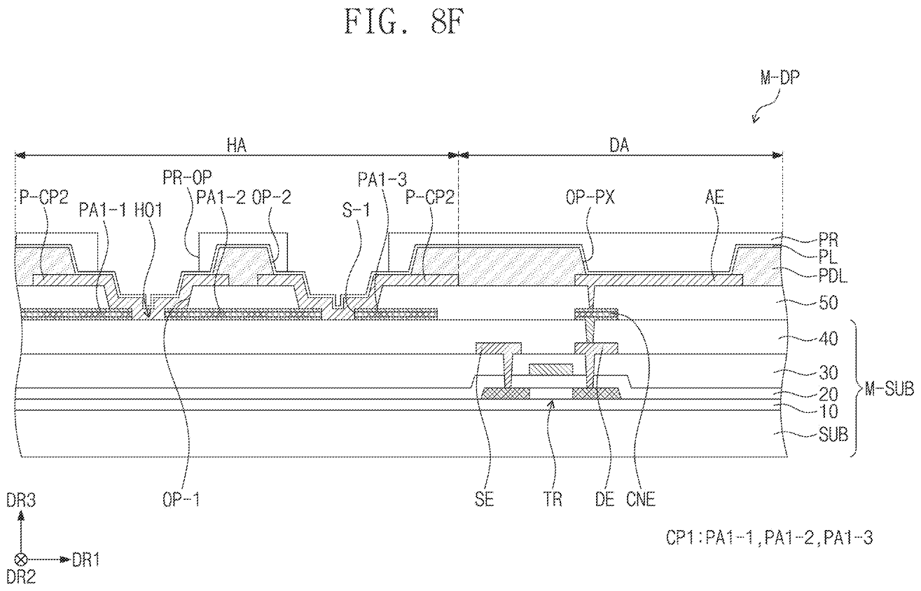

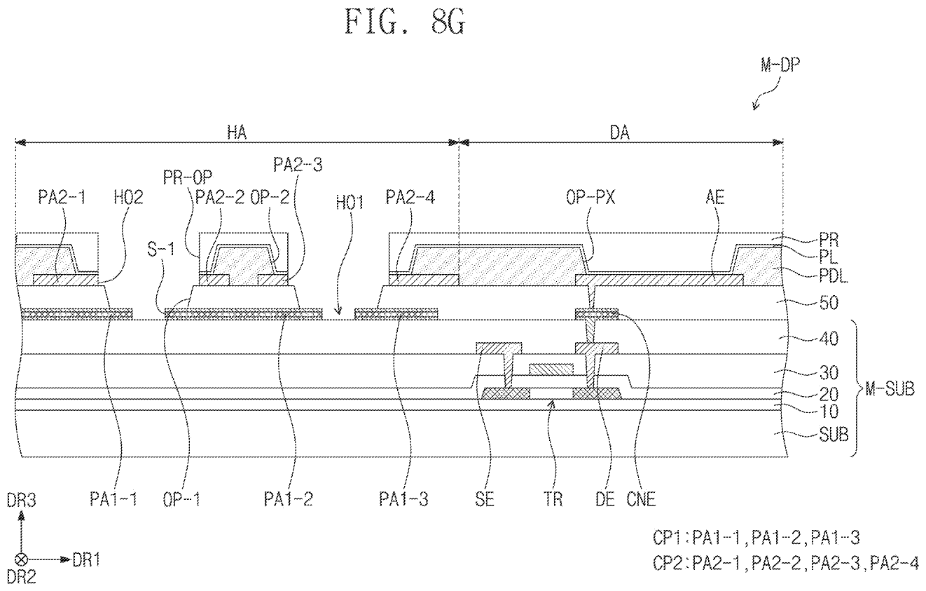

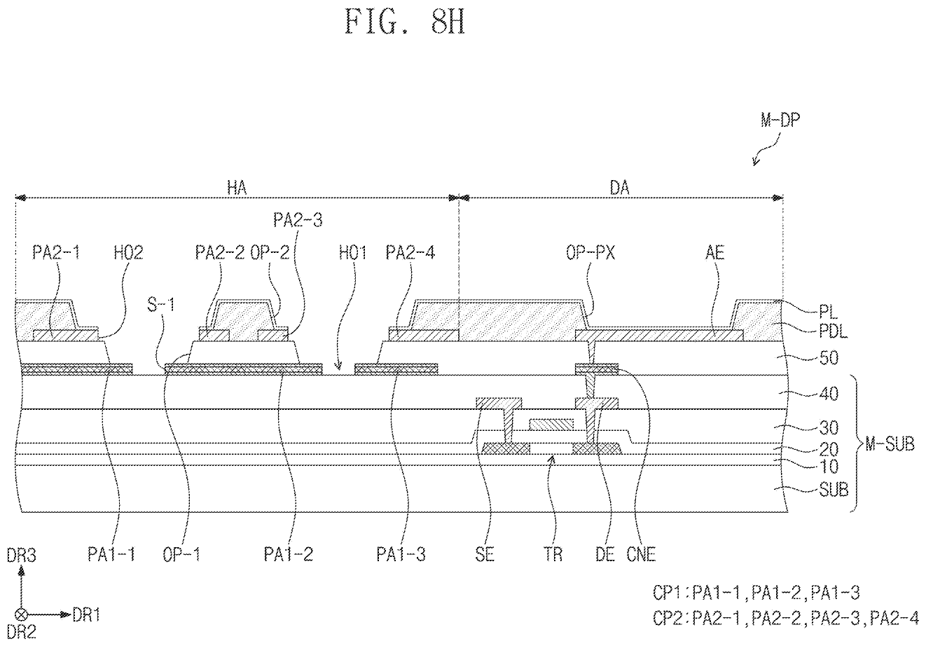

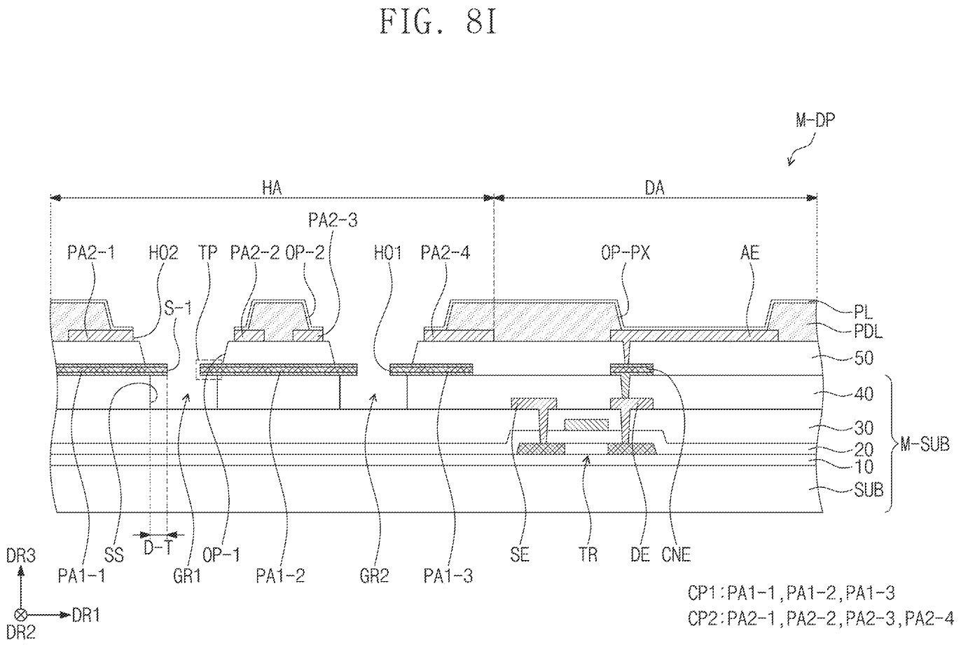

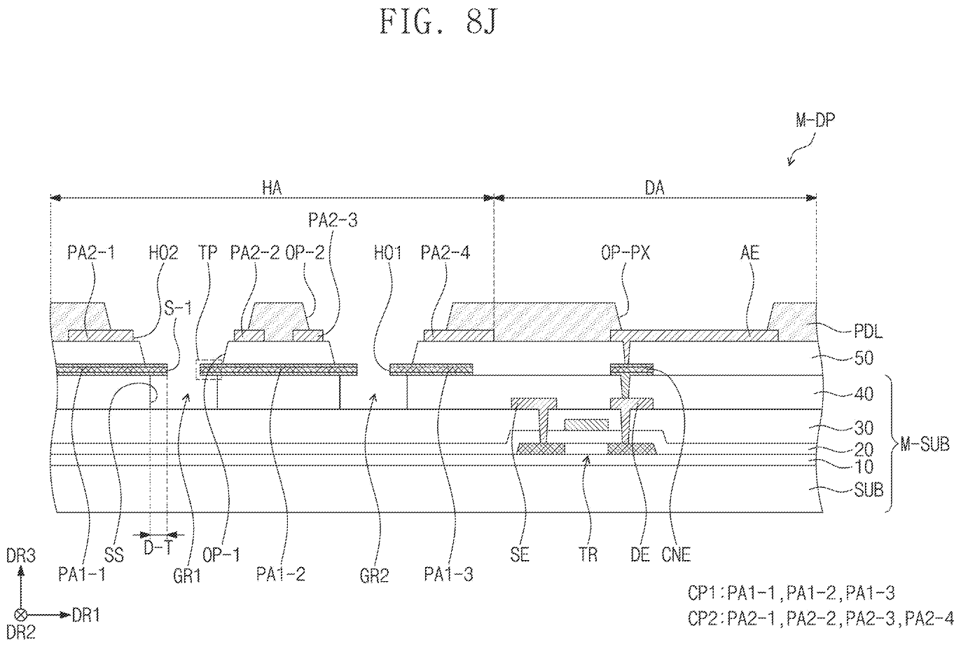

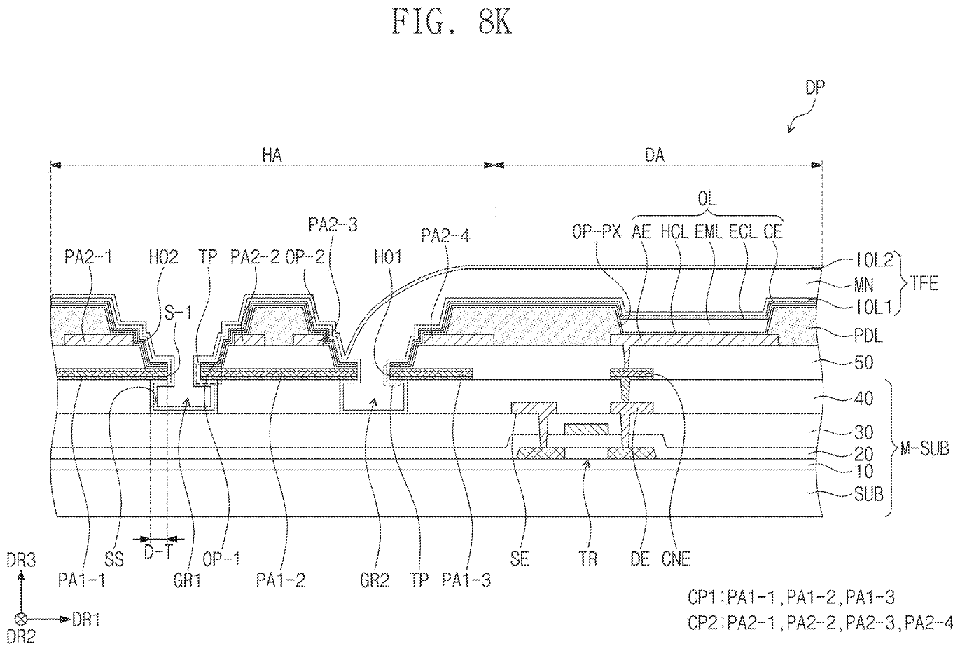

The second conductive pattern CP2 may be disposed at (e.g., in or on) the same layer as that of the pixel electrode AE of the display element layer DP-OL. The second conductive pattern CP2 may be spaced apart from the pixel electrode AE when viewed in the plane (e.g., in a plan view). The second conductive pattern CP2 may be formed when the pixel electrode AE is formed. When the pixel electrode AE is formed, a preliminary second conductive pattern P-CP2 (e.g., refer to FIG. 8C) may cover the side surface S-1 of the tip portion TP of the first conductive pattern SP1, before the second pattern portions PA2-1, PA2-2, PA2-3, and PA2-4 defining the second pattern holes HO2 are formed. Accordingly, the tip portion TP may be prevented or substantially prevented from being damaged, or by-products may be prevented or substantially prevented from being formed at (e.g., in or on) the tip portion TP, in the process of forming the pixel electrode AE, and thus, the tip portion TP may be formed with the desired length (e.g., the predetermined length) D-T. As an example, the length D-T of the tip portion TP may be equal to or greater than about 1.2 μm, or in more detail, about 1.5 μm or more. However, the length D-T of the tip portion TP is not limited thereto or thereby.

As the tip portion TP has the desired length (e.g., the predetermined length) D-T, continuity of the hole control layer HCL, the electron control layer ECL, and the common electrode CE disposed at (e.g., in or on) the hole area HA may be blocked by the tip portion TP. Accordingly, moisture, oxygen, and/or external contaminants may be prevented or substantially prevented from entering the display area DA through the hole control layer HCL, the electron control layer ECL, or the common electrode CE, and reliability of the display panel DP may be improved.

The second pattern hole HO2 may overlap with a corresponding first pattern hole HO1 and a corresponding groove pattern GR1 and GR2. From among the second pattern portions PA2-1, PA2-2, PA2-3, and PA2-4, two second pattern portions that are disposed adjacent to each other may define one second pattern hole HO2. In the case where the plurality of groove patterns GR1 and GR2 are disposed at (e.g., in or on) the hole area HA, the second conductive pattern CP2 may define a plurality of second pattern holes HO2 corresponding to the plurality of groove patterns GR1 and GR2, respectively. The number of the second pattern holes HO2 defined by the second pattern portions PA2-1, PA2-2, PA2-3, and PA2-4 may be greater than the number of the groove patterns GR1 and GR2 disposed at (e.g., in or on) the hole area HA. Accordingly, some of the second pattern holes HO2 may overlap with the groove patterns GR1 and GR2, and others of the second pattern holes HO2 may overlap with the fourth insulating layer 40, but the present disclosure is not limited thereto or thereby. According to an embodiment, the number of the second pattern holes HO2 defined by the second pattern portions PA2-1, PA2-2, PA2-3, and PA2-4 may be equal to the number of the groove patterns GR1 and GR2, and in this case, the second pattern holes HO2 may overlap with the groove patterns GR1 and GR2, respectively.

The second pattern hole HO2 may have a width greater than the width of the first pattern hole HO1 in the first direction DR1. Side surfaces of the second pattern portions PA2-1, PA2-2, PA2-3, and PA2-4 defining the second pattern holes HO2 may be spaced apart from the tip portion TP. Accordingly, the tip portion TP and the first pattern hole HO1 of the first conductive pattern CP1 may be exposed through the second pattern hole HO2.

The pixel definition layer PDL may be disposed on the second conductive pattern CP2. The pixel definition layer PDL may be provided with a second opening OP-2 overlapping with the second pattern hole HO2. The second opening OP-2 may expose the side surfaces of the second pattern portions PA2-1, PA2-2, PA2-3, and PA2-4 defining the second pattern hole HO2. From among the second pattern holes HO2, the second pattern hole HO2 overlapping with the groove patterns GR1 and GR2 may be exposed without being covered by the pixel definition layer PDL, and the second pattern hole HO2 that does not overlap with the groove patterns GR1 and GR2 may be covered by the pixel definition layer PDL. Accordingly, the pixel definition layer PDL may cover a portion of the side surfaces of the second pattern portions PA2-1, PA2-2, PA2-3, and PA2-4. An end of the second conductive pattern CP2 spaced apart from the second pattern hole HO2, which overlaps with the corresponding groove pattern GR1 and GR2, may be covered by the pixel definition layer PDL.

The hole control layer HCL, the electron control layer ECL, and the common electrode CE, which may be provided as the common layers, may cover a side surface of the pixel definition layer PDL, which is exposed through the second opening OP-2 defined through the pixel definition layer PDL.

The first and second inorganic layers IOL1 and IOL2 disposed on the common electrode CE may cover the common electrode CE. Side surfaces S-2 of the hole control layer HCL, the electron control layer ECL, and the common electrode CE, in which the continuity thereof is blocked by the tip portion TP at (e.g., in or on) the hole area HA, may be covered by the first and second inorganic layers IOL1 and IOL2. In addition, the side surface S-1 of the tip portion TP may be covered by the first and second inorganic layers IOL1 and IOL2. In other words, the first and second inorganic layers IOL1 and IOL2 may extend from an upper surface of the common electrode CE, and may cover the side surfaces S-2 of the hole control layer HCL, the electron control layer ECL, and the common electrode CE, the side surface S-1 of the tip portion TP, and the inner surface of the groove patterns GR1 and GR2. Accordingly, moisture and/or oxygen may be prevented or substantially prevented from entering through the hole control layer HCL, the electron control layer ECL, the common electrode CE, and the first conductive pattern CP1.

Referring to FIG. 6A, the side surface S-1 of the tip portion TP, which defines the first pattern hole HO1, may be defined by the side surfaces of the conductive layers M1, M2, and M3. The side surfaces of the conductive layers M1, M2, and M3 may be arranged or substantially arranged along the third direction DR3. Accordingly, the first and second inorganic layers IOL1 and IOL2 disposed on the side surfaces of the conductive layers M1, M2, and M3 may cover the side surfaces of the conductive layers M1, M2, and M3 without being damaged or cracked.

The display panel DP shown in FIG. 6B may have the same or substantially the same structure as that of the display panel DP shown in FIG. 6A, and thus, redundant description thereof may not be repeated. Hereinafter, features of the display panel DP shown in FIG. 6B that may be different from those of the display panel DP shown in FIG. 6A will be mainly described in more detail.

Referring to FIG. 6B, the display panel DP may further include a deposition pattern EP disposed in a first groove pattern GR1. The deposition pattern EP may correspond to a portion of a common layer in which the continuity thereof is blocked by a tip portion TP at (e.g., in or on) a hole area HA. As an example, the deposition pattern EP may include the same materials as those of the hole control layer HCL, the electron control layer ECL, and the common electrode CE, which are sequentially stacked, and may include the layers stacked in the same order as that of the hole control layer HCL, the electron control layer ECL, and the common electrode CE. The deposition pattern EP may be spaced apart from the hole control layer HCL, the electron control layer ECL, and the common electrode CE, which are disposed on the tip portion TP, so that continuity of the hole control layer HCL, the electron control layer ECL, and the common electrode CE is blocked at (e.g., in or on) hole area HA.

The deposition pattern EP may be formed in a process of depositing the hole control layer HCL, the electron control layer ECL, and the common electrode CE, which are provided as the common layers, when portions thereof are deposited on the inner bottom surface BS of the first groove pattern GR1 after the first groove pattern GR1 and the tip portion TP are formed. As the length D-T of the tip portion TP is controlled, the deposition pattern EP may not be disposed on the inner side surface SS of the first groove pattern GR1 as shown in FIG. 6A, or the deposition pattern EP may be spaced apart from the hole control layer HCL, the electron control layer ECL, and the common electrode CE disposed on the tip portion TP as shown in FIG. 6B, and thus, the continuity thereof may be blocked.

In the present embodiment, while the first groove pattern GR1 shown in FIG. 6B is described in more detail, the description thereof may be applied to the second groove pattern GR2 in the same or substantially the same (or similar) manner, and thus, redundant description thereof may not be repeated. For example, the deposition pattern EP may be disposed in the second groove pattern GR2.

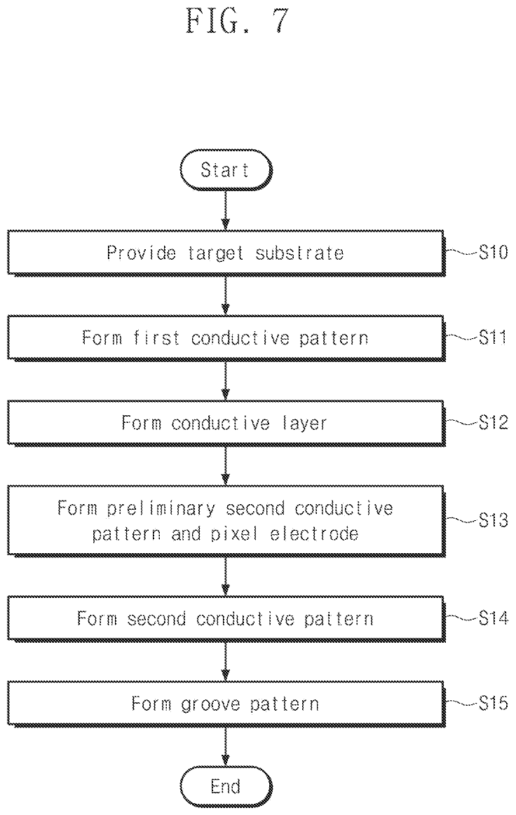

FIG. 7 is a flowchart of a method of manufacturing the display panel DP according to an embodiment of the present disclosure. FIGS. 8A through 8K are cross-sectional views of a method of manufacturing the display panel DP according to an embodiment of the present disclosure.

Referring to FIG. 7, the manufacturing method of the display panel may include providing a target substrate (S10), forming the first conductive pattern (S11), forming the conductive layer (S12), forming a preliminary second conductive pattern and the pixel electrode (S13), forming the second conductive pattern (S14), and forming the groove pattern (S15). Hereinafter, the manufacturing method of the display panel shown in FIG. 7 will be described in more detail with reference to FIGS. 8A to 8K.

FIG. 8A shows a process of forming the first conductive pattern CP1 (S11) after the providing of the target substrate M-SUB (S10). FIG. 8A shows a cross-section of a panel substrate M-DP, in which the first conductive pattern CP1 and the fifth insulating layer 50 are formed on the target substrate M-SUB. In the present embodiment, the panel substrate M-DP may be defined as a substrate to be processed before the display panel DP (e.g., refer to FIG. 5) is completed in the manufacturing process of the display panel DP.

Referring to FIG. 8A, the target substrate M-SUB may include the base substrate SUB, the insulating layers 10, 20, 30, and 40, and the transistor TR, which have been described above.

The first conductive pattern CP1 may be formed on the fourth insulating layer 40 of the target substrate M-SUB, and the fifth insulating layer 50 may be formed on the first conductive pattern CP1.

The first conductive pattern CP1 may include the first pattern portions PA1-1, PA1-2, and PA1-3 that are spaced apart from each other. The first pattern holes HO1 may be defined by the spaces between the first pattern portions PA1-1, PA1-2, and PA1-3. The area in which the first pattern holes HO1 are defined may correspond to an area in which the groove patterns GR1 and GR1 are formed.

The first conductive pattern CP1 may be disposed at (e.g., in or on) the same layer as that of the connection electrode CNE disposed at (e.g., in or on) the display area DA. The first conductive pattern CP1 and the connection electrode CNE may be disposed on the fourth insulating layer 40. The first conductive pattern CP1 may include the same material as that of the connection electrode CNE.

The first conductive pattern CP1 and the connection electrode CNE may be concurrently (e.g., simultaneously or substantially simultaneously) formed through the same process. As an example, a plurality of conductive layers for the first conductive pattern CP1 and the connection electrode CNE may be formed on the fourth insulating layer 40, and the conductive layers may be patterned to form the first conductive pattern CP1, and the connection electrode CNE spaced apart from the first conductive pattern CP1. Accordingly, the first conductive pattern CP1 may be formed at (e.g., in or on) the hole area HA without an additional separate process.

The first opening OP-1 may be formed through the fifth insulating layer 50, and may overlap with the first pattern hole HO1. In the first direction DR1, the width of the first opening OP-1 may be greater than the width of the first pattern hole HO1. Accordingly, an upper surface of the first pattern portions PA1-1, PA1-2, and PA1-3 that are adjacent to the first pattern hole HO1 may be exposed through the first opening OP-1. When the first pattern hole HO1 is provided in a plurality, the first opening OP-1 may be provided in a plurality to correspond to the first pattern holes HO1, respectively.

FIG. 8B is a cross-sectional view showing a process of forming of the conductive layer CL (S12) on the panel substrate M-DP shown in FIG. 8A. Referring to FIG. 8B, the conductive layer CL may be disposed on the fifth insulating layer 50. The conductive layer CL may be disposed at (e.g., in or on) the display area DA and the hole area HA.

The conductive layer CL may overlap with the connection electrode CNE and the first conductive pattern CP1. The conductive layer CL may cover the side surface of the fifth insulating layer 50, which is exposed through the first opening OP-1, and the side surfaces S-1 of the first pattern portions PA1-1, PA1-2, and PA1-3. The conductive layer CL may be patterned to form the preliminary second conductive pattern P-CP2 and the pixel electrode AE shown in FIG. 8C.

FIG. 8C is a cross-sectional view showing a process of forming the preliminary second conductive pattern P-CP2 and the pixel electrode AE (S13) from the conductive layer CL shown FIG. 8B. Referring to FIG. 8C, the pixel electrode AE may be formed at (e.g., in or on) an area defined as the light emitting area within the display area DA. The pixel electrode AE may be connected to the connection electrode CNE through the contact hole defined (e.g., penetrating) through the fifth insulating layer 50.

The preliminary second conductive pattern P-CP2 may be formed at (e.g., in or on) the hole area HA to cover the first pattern hole HO1 of the first conductive pattern CP1. In a case where the plurality of first pattern holes HO1 are defined through the first conductive pattern CP1, the preliminary second conductive pattern P-CP2 may be provided in a plurality, and the preliminary second conductive patterns P-CP2 may cover the first pattern holes HO1, respectively, but the present disclosure is not limited thereto or thereby. According to an embodiment, the preliminary second conductive pattern P-CP2 may be provided as a single integral layer to entirely cover the first pattern holes HO1. The preliminary second conductive pattern P-CP2 is not particularly limited, as long as the preliminary second conductive pattern P-CP2 covers the side surfaces S-1 of the first pattern portions PA1-1, PA1-2, and PA1-3, which define the first pattern holes HO1.

The preliminary second conductive pattern P-CP2 and the pixel electrode AE may be formed from the patterned conductive layer CL. The preliminary second conductive pattern P-CP2 and the pixel electrode AE may be concurrently (e.g., simultaneously or substantially simultaneously) formed with each other by wet-etching the conductive layer CL. In a case where the conductive layer CL formed on the first pattern portions PA1-1, PA1-2, and PA1-3 adjacent to the first pattern holes HO1 is etched so as not to form the preliminary second conductive pattern P-CP2, the side surfaces S-1 of the first pattern portions PA1-1, PA1-2, and PA1-3 may be exposed to an etchant during the etching process. However, according to one or more embodiments, as the preliminary second conductive pattern P-CP2 is formed together with the pixel electrode AE in the etching process of the conductive layer CL, the side surfaces S-1 of the first pattern portions PA1-1, PA1-2, and PA1-3 may not be exposed to the etchant. Accordingly, the side surfaces S-1 of the first pattern portions PA1-1, PA1-2, and PA1-3 may be protected from the etchant.

As described above, each of the first pattern portions PA1-1, PA1-2, and PA1-3 of the first conductive pattern CP1 may include the conductive layers M1, M2, and M3 (e.g., refer to FIG. 6A). In the case where the side surfaces S-1 of the first pattern portions PA1-1, PA1-2, and PA1-3 are exposed in the etching process to form the pixel electrode AE, the side surfaces S-1 of the first pattern portions PA1-1, PA1-2, and PA1-3 may be etched. There may be a difference in an etch rate between the conductive layers M1, M2, and M3 (e.g., refer to FIG. 6A) defining the side surfaces S-1 of the first pattern portions PA1-1, PA1-2, and PA1-3 with respect to the same etchant. As an example, the second conductive layer M2 disposed at a center location may be etched faster than the first and third conductive layers M1 and M3, and in this case, the first pattern portions PA1-1, PA1-2, and PA1-3 may have an undercut shape in which the side surface of the second conductive layer M2 is concaved. However, according to one or more embodiments, as the preliminary second conductive pattern P-CP2 protects the side surfaces S-1 of the first pattern portions PA1-1, PA1-2, and PA1-3 from the etchant, the undercut shape may be prevented or substantially prevented from being formed in the side surfaces S-1 of the first pattern portions PA1-1, PA1-2, and PA1-3.

In addition, in the case where the side surfaces S-1 of the first pattern portions PA1-1, PA1-2, and PA1-3 are exposed, particles of the conductive layer CL (e.g., refer to FIG. 8B) in the patterning process may be deposited on the side surfaces S-1 of the first pattern portions PA1-1, PA1-2, and PA1-3, and may react with substances of the first pattern portions PA1-1, PA1-2, and PA1-3 in the etching process of forming the pixel electrode AE. As a result, by-products such as particles may be formed, and process reliability of the display panel may be deteriorated. However, according to one or more embodiments, because the preliminary second conductive pattern P-CP2 protects the side surfaces S-1 of the first pattern portions PA1-1, PA1-2, and PA1-3, the formation of the by-products may be prevented or substantially prevented, and process reliability may be improved.

Because the preliminary second conductive pattern P-CP2 covers the upper surfaces of the first pattern portions PA1-1, PA1-2, and PA1-3 exposed through the first opening OP-1, the upper surfaces of the first pattern portions PA1-1, PA1-2, and PA1-3 may be prevented or substantially prevented from being in contact with the etchant. Accordingly, the first pattern portions PA1-1, PA1-2, and PA1-3 may be prevented or substantially prevented from being etched with the conductive layer CL (e.g., refer to FIG. 8B) by the etchant, and a length of the upper surfaces of the first pattern portions PA1-1, PA1-2, and PA1-3 exposed through the first opening OP-1 may be maintained or substantially maintained in a desired length (e.g., a predetermined length) D-PA.

FIG. 8D is a cross-sectional view showing a process of forming a preliminary pixel definition layer P-PDL. Referring to FIG. 8D, the preliminary pixel definition layer P-PDL may be formed on the preliminary second conductive pattern P-CP2 and the pixel electrode AE. The preliminary pixel definition layer P-PDL may be an insulating layer formed at (e.g., in or on) the display area DA and the hole area HA as a single integral layer. The preliminary pixel definition layer P-PDL may include an organic material or an inorganic material, but is not limited thereto or thereby. According to an embodiment, the preliminary pixel definition layer P-PDL may include an organic material, in which an inorganic material is distributed.

FIG. 8E is a cross-sectional view showing a process of patterning the preliminary pixel definition layer P-PDL shown in FIG. 8D, to form the light emitting opening OP-PX and the second opening OP-2 through the preliminary pixel definition layer P-PDL. As shown in FIG. 8E, the insulating layer obtained by forming the light emitting opening OP-PX and the second opening OP-2 through the preliminary pixel definition layer P-PDL may be defined as the pixel definition layer PDL.

The light emitting opening OP-PX may overlap with the display area DA, and at least a portion of the pixel electrode AE may be exposed through the light emitting opening OP-PX. The portion of the pixel electrode AE exposed through the light emitting opening OP-PX may be defined as the light emitting area for emitting light in the display area DA. The pixel definition layer PDL adjacent to the light emitting opening OP-PX may cover an end of the pixel electrode AE.

The second opening OP-2 may overlap with the hole area HA, and at least a portion of the preliminary second conductive pattern P-CP2 may be exposed through the second opening OP-2. The second opening OP-2 may overlap with the first pattern hole HO1 of the first conductive pattern CP1. The preliminary second conductive pattern P-CP2 exposed through the second opening OP-2 may be patterned through a subsequent process. The pixel definition layer PDL may cover an end of the preliminary second conductive pattern P-CP2 that is spaced apart from the first pattern hole HO1.

FIG. 8F is a cross-sectional view showing a process of patterning the preliminary second conductive pattern P-CP2. Referring to FIG. 8F, a protective layer PL may be formed on the panel substrate M-DP on which the pixel definition layer PDL is formed. The protective layer PL may overlap with the display area DA and the hole area HA. The protective layer PL may protect components disposed thereunder and overlapping with the protective layer PL in the etching process. As an example, the protective layer PL may include indium-gallium-zinc oxide (IGZO). However, the material for the protective layer PL is not limited thereto or thereby.

A photoresist layer PR may be disposed on the protective layer PL. An exposure and development process may be performed on the photoresist layer PR using a mask, and thus, a photo opening PR-OP may be formed through the photoresist layer PR. The photoresist layer PR may be patterned through a positive photolithography process, in which a portion of the photoresist layer PR corresponding to an opening of the mask is removed, but the present disclosure is not limited thereto or thereby. The photoresist layer PR may be patterned through a negative photolithography process, in which the portion of the photoresist layer PR corresponding to the opening of the mask remains as a pattern.

The portion of an upper surface of the protective layer PL disposed on the preliminary second conductive pattern P-CP2 may be exposed through the photo opening PR-OP. The photo opening PR-OP may overlap with the first pattern hole HO1 and the preliminary second conductive pattern P-CP2. The photo opening PR-OP may correspond to portions of the protective layer PL and the preliminary second conductive pattern P-CP2, which are removed through the patterning process.

FIG. 8G is a cross-sectional view showing a process of forming the second conductive pattern CP2 (S14) from the preliminary second conductive pattern P-CP2. Referring to FIG. 8G, the portion of the upper surface of the protective layer PL and the preliminary second conductive pattern P-CP2 (e.g., refer to FIG. 8F), which are exposed through the photo opening PR-OP, may be etched. Accordingly, the second conductive pattern CP2 may be formed from the preliminary second conductive pattern P-CP2 (e.g., refer to FIG. 8F).

The second conductive pattern CP2 may include the second pattern portions PA2-1, PA2-2, PA2-3, and PA2-4. The second pattern holes HO2 may be defined by the second pattern portions PA2-1, PA2-2, PA2-3, and PA2-4. At least a portion of the second pattern holes HO2 may overlap with the first pattern hole HO1. The width of the second pattern hole HO2 overlapping with the first pattern hole HO1 may be greater than the width of the first pattern hole HO1 in the first direction DR1. The width of the second pattern hole HO2 overlapping with the first pattern hole HO1 may be greater than the width of the first opening OP-1 of the fifth insulating layer 50 in the first direction DR1. Accordingly, the portion of the upper surface of the first pattern portions PA1-1, PA1-2, and PA1-3 exposed through the first opening OP-1 and the first pattern hole HO1 may be exposed through the second pattern hole HO2.

The second conductive pattern CP2 may be formed on the fifth insulating layer 50. The second conductive pattern CP2 may be disposed at (e.g., in or on) the same layer as that of the pixel electrode AE. The second conductive pattern CP2 may include the same material as that of the pixel electrode AE.

FIG. 8H is a cross-sectional view showing a process of removing the photoresist layer PR (e.g., refer to FIG. 8G). Referring to FIG. 8H, the photoresist layer PR (refer to FIG. 8G) disposed on the protective layer PL may be removed. The portion of the protective layer PL and the portion of the preliminary second conductive pattern P-CP2 (e.g., refer to FIG. 8F), which correspond to the photo opening PR-OP, may be removed, and thus, the through hole may be formed through the protective layer PL to overlap with the second pattern hole HO2. Accordingly, the portion of the upper surface of the fourth insulating layer 40 overlapping with the first pattern hole HO1 may be exposed.

The protective layer PL covered by the photoresist layer PR (e.g., refer to FIG. 8G) may remain on the panel substrate M-DP after the photoresist layer PR is removed. The protective layer PL may protect components of the panel substrate M-DP, which are disposed in an area other than an area in which the groove patterns GR1 and GR2 (e.g., refer to FIG. 8I) are formed, in an etching process of forming the groove patterns GR1 and GR2.

FIG. 8I is a cross-sectional view showing a process of forming the groove patterns GR1 and GR2 (S15). FIG. 8I shows the forming of the first and second groove patterns GR1 and GR2 as a representative example.

Referring to FIG. 8I, the first and second groove patterns GR1 and GR2 may be formed by etching at least one insulating layer disposed under (e.g., underneath) the first conductive pattern CP1. As shown in FIG. 8I, the first and second groove patterns GR1 and GR2 may be formed through the fourth insulating layer 40. The inner surfaces of the first and second groove patterns GR1 and GR2 may be defined by the inner side surface SS of the fourth insulating layer 40 and the upper surface of the third insulating layer 30 exposed without being covered by the fourth insulating layer 40, but the present disclosure is not limited thereto or thereby. According to an embodiment, the first and second groove patterns GR1 and GR2 may be formed by etching a portion of the fourth insulating layer 40 in the third direction DR3.

The first and second groove patterns GR1 and GR2 may be formed by dry-etching the fourth insulating layer 40. The protective layer PL may protect components of the panel substrate M-DP, which are disposed to overlap with the protective layer PL, in the dry-etching of the fourth insulating layer 40.

The side surfaces S-1 of the first pattern portions PA1-1, PA1-2, and PA1-3 defining the first pattern hole HO1 may protrude more toward the center of the groove pattern GR1 and GR2 compared with the inner side surfaces SS of the fourth insulating layer 40, which define the first and second groove patterns GR1 and GR2. Accordingly, the tip portion TP may be formed in the first conductive pattern CP1 to be adjacent to the first pattern hole HO1. The tip portion TP may have the desired length (e.g., the predetermined length) D-T corresponding to a distance between the inner side surface SS of the fourth insulating layer 40 and the side surface S-1 of the first pattern portions PA1-1, PA1-2, and PA1-3 in the first direction DR1.

In a case where the fifth insulating layer 50 including the organic layer rather than the preliminary second conductive pattern P-CP2 (e.g., refer to FIG. 8F) is used to protect the first pattern portions PA1-1, PA1-2, and PA1-3 of the first conductive pattern CP1, the fifth insulating layer 50 may cover the side surfaces S-1 of the first pattern portions PA1-1, PA1-2, and PA1-3. In this case, not only the fourth insulating layer 40, but also the fifth insulating layer 50 adjacent to the first pattern hole HO1, may be etched to form the tip portion TP, while the side surfaces S-1 of the first pattern portions PA1-1, PA1-2, and PA1-3 are exposed. However, in this case, a time consumed to sufficiently etch the fifth insulating layer 50 may be increased, or the fourth and fifth insulating layers 40 and 50 may be etched insufficiently due to a thickness of the fifth insulating layer 50, and thus, the length D-T of the tip portion TP may be reduced.

However, according to one or more embodiments of the present disclosure, when the first conductive pattern CP1 is protected by using the preliminary second conductive pattern P-CP2 (e.g., refer to FIG. 8F), and the second conductive pattern CP2 is formed from the preliminary second conductive pattern P-CP2 after the protection of the first conductive pattern CP1, a portion of the upper surface of the fourth insulating layer 40, which is etched, may be completely exposed. Accordingly, the fourth insulating layer 40 may be etched sufficiently, and the groove patterns GR1 and GR2 may be formed according to specifications. As a result, the tip portion TP may be formed to have the desired length D-T.

FIG. 8J is a cross-sectional view showing a process of removing the protective layer PL. After the groove patterns GR1 and GR2 are formed, the protective layer PL that is disposed on the panel substrate M-DP may be completely removed. Accordingly, an upper surface of the pixel definition layer PDL may be exposed to the outside.

FIG. 8K is a cross-sectional view showing a process of forming the light emitting element OL and the encapsulation layer TFE on the panel substrate M-DP on which the first and second conductive patterns CP1 and CP2 and the groove patterns GR1 and GR2 are formed. FIG. 8K shows a cross-section of a portion of the display panel DP manufactured by the manufacturing method of the display panel.

Referring to FIG. 8K, the light emitting element OL may include the pixel electrode AE, the common electrode CE, the hole control layer HCL, the light emitting layer EML, and the electron control layer ECL. The hole control layer HCL, the light emitting layer EML, and the electron control layer ECL may be disposed between the pixel electrode AE and the common electrode CE. The hole control layer HCL may be disposed on the pixel electrode AE.

The light emitting layer EML may be formed on the hole control layer HCL. As an example, the light emitting layer EML may be formed by depositing a light emitting material in an area corresponding to the light emitting opening OP-PX using a deposition mask provided with an opening defined therethrough to correspond to the light emitting opening OP-PX.

The electron control layer ECL may be formed on the light emitting layer EML. The common electrode CE may be formed on the electron control layer ECL. The hole control layer HCL, the electron control layer ECL, and the common electrode CE of the light emitting element OL may be provided as the common layers overlapping with the pixels. As an example, the hole control layer HCL, the electron control layer ECL, and the common electrode CE may be formed by the deposition process using an open mask. Accordingly, the hole control layer HCL, the electron control layer ECL, and the common electrode CE may extend from the display area DA, and may be disposed at (e.g., in or on) the hole area HA.

The continuity of the hole control layer HCL, the electron control layer ECL, and the common electrode CE, which are disposed at (e.g., in or on) the hole area HA, may be blocked by the tip portion TP of the first conductive pattern CP1. Accordingly, the path through which moisture and/or contaminants, which may enter into the hole area HA, that may move to the display area DA through the hole control layer HCL, the electron control layer ECL, and the common electrode CE may be blocked, and the reliability of the display panel DP may be improved.

After the light emitting element OL is formed, the encapsulation layer TFE may be formed. The encapsulation layer TFE may be formed by sequentially depositing the first inorganic layer IOL1, the organic layer MN, and the second inorganic layer IOL2. The first inorganic layer IOL1 and the second inorganic layer IOL2 may be formed at (e.g., in or on) the display area DA and the hole area HA using a chemical vapor deposition method. However, the process of forming the first and second inorganic layers IOL1 and IOL2 is not limited thereto or thereby.

The first inorganic layer IOL1 may encapsulate the light emitting element OL. In addition, the first inorganic layer IOL1 may encapsulate the exposed surfaces of the pixel definition layer PDL, the fifth insulating layer 50, the first conductive pattern CP1, the second conductive pattern CP2, and the groove patterns GR1 and GR2. Therefore, moisture may be prevented or substantially prevented from entering the components of the display panel DP, and the reliability of the display panel DP may be improved.

The preliminary second conductive pattern P-CP2 (e.g., refer to FIG. 8F) may prevent or substantially prevent a step difference from being generated between the conductive layers of the first pattern portions PA1-1, PA1-2, and PA1-3, which form the tip portion TP, and thus, the undercut shape may be prevented or substantially prevented from being formed in the side surfaces S-1 of the first pattern portions PA1-1, PA1-2, and PA1-3. Accordingly, the first inorganic layer IOL1 formed on the side surfaces S-1 of the first pattern portions PA1-1, PA1-2, and PA1-3 may be prevented or substantially prevented from being disconnected or cracked. As a result, a process reliability may be improved, and the first inorganic layer IOL1 may effectively prevent moisture and/or oxygen from entering.

The organic layer MN may be formed by coating the organic resin in the liquid state at (e.g., in or on) the display area DA using an inkjet method. However, the process of forming the organic layer MN is not limited thereto or thereby. A fluidity of the organic resin in the liquid state may be controlled by the groove patterns GR1 and GR2 disposed at (e.g., in or on) the hole area HA, and the organic layer MN may be spaced apart from at least one of the groove patterns GR1 and GR2. The organic layer MN may be encapsulated by the first and second inorganic layers IOL1 and IOL2, and thus, moisture may be prevented or substantially prevented from entering.

The hole HH (e.g., refer to FIG. 5) may be formed through the display panel DP in the area surrounded (e.g., around a periphery thereof) by the groove patterns GR1 and GR2 within the hole area HA by a subsequent process. As an example, the hole HH (e.g., refer to FIG. 5) may be formed by using a laser beam, but the process of forming the hole HH is not limited thereto or thereby.

According to one or more embodiments of the present disclosure, the first conductive pattern may be disposed at (e.g., in or on) the hole area, and may include the tip portion disposed on (e.g., protruding over) the groove pattern. As the tip portion has the suitable length, the continuity of the functional layer extending from the display area and disposed at (e.g., in or on) the hole area may be blocked. Because the continuity of the functional layer is blocked in the hole area, a path through which moisture and/or contaminants that may enter through the hole area and move to the display area may be blocked.

According to one or more embodiments of the present disclosure, in the manufacturing method of the display panel, the tip portion of the first conductive pattern may be formed to have the suitable length in the process of forming the first conductive pattern and the groove pattern. In addition, the side surfaces of the first conductive pattern may not be exposed to the etchant in the etching process to form the pixel electrode. Thus, by-products may be prevented or substantially prevented from being generated, and the tip portion may be prevented or substantially prevented from being damaged. In addition, the inflow of moisture and/or oxygen may be effectively blocked by allowing the inorganic layer to be deposited properly at (e.g., in or on) the tip portion and the groove pattern.

is notis not Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display panel comprising:
a base substrate having a hole defined therethrough;
a thin film transistor on the base substrate, and spaced from the hole;
a light emitting element comprising a pixel electrode spaced from the hole, and connected to the thin film transistor;
a first insulating layer between the base substrate and the pixel electrode, and having a groove pattern defined therein between the pixel electrode and the hole in a plan view;
a first conductive pattern spaced from the pixel electrode, and comprising a tip portion defining a first pattern hole overlapping with the groove pattern; and
a second conductive pattern spaced from the pixel electrode, and having a second pattern hole defined therethrough, and overlapping with the first pattern hole.

2. The display panel of claim 1, wherein the second conductive pattern is at a same layer as that of the pixel electrode.

3. The display panel of claim 1, wherein the second conductive pattern comprises a same material as that of the pixel electrode.

4. The display panel of claim 1, wherein the second conductive pattern comprises a material different from a material of the first conductive pattern.

5. The display panel of claim 1, wherein the tip portion has a side surface defining the first pattern hole, and protruding more toward a center of the first pattern hole than an inner side surface of the first insulating layer defining the groove pattern.

6. The display panel of claim 5, wherein the first conductive pattern comprises a plurality of conductive layers, and the side surface of the tip portion is defined by side surfaces of the conductive layers.

7. The display panel of claim 1, wherein the second pattern hole has a width greater than a width of the first pattern hole in a plan view.

8. The display panel of claim 1, wherein the groove pattern surrounds the hole in a plan view.

9. The display panel of claim 1, further comprising a connection electrode connecting the thin film transistor to the pixel electrode,
wherein the first conductive pattern is at a same layer as that of the connection electrode.

10. The display panel of claim 9, wherein the first conductive pattern comprises a same material as that of the connection electrode.

11. The display panel of claim 1, further comprising a pixel definition layer having a light emitting opening defined therethrough to expose at least a portion of the pixel electrode, and a first opening defined therethrough to expose at least a portion of the second conductive pattern.

12. The display panel of claim 11, wherein the second conductive pattern comprises one side surface defining the second pattern hole, and another side surface opposite to the one side surface, and
wherein the one side surface is exposed through the first opening, and the other side surface is covered by the pixel definition layer.

13. The display panel of claim 1, further comprising an encapsulation layer on the light emitting element, and comprising:
a plurality of inorganic layers; and
an organic layer between the inorganic layers,
wherein at least one of the inorganic layers covers an inner side surface of the first insulating layer that defines the groove pattern.

14. The display panel of claim 13, wherein the at least one of the inorganic layers covers a side surface of the tip portion that defines the first pattern hole.

15. The display panel of claim 13, wherein the groove pattern comprises a plurality of groove patterns, at least one of the plurality of groove patterns overlaps with the organic layer, and another of the plurality of groove patterns is spaced from the organic layer.

16. The display panel of claim 1, further comprising a second insulating layer between the pixel electrode and the first insulating layer,
wherein the second insulating layer is between the first conductive pattern and the second conductive pattern, and has a second opening defined therethrough, and overlapping with the first pattern hole in a plan view.

17. An electronic device comprising:
a base substrate comprising:
a hole area having a hole;
a display area surrounding at least a portion of the hole area in a plan view; and
a non-display area adjacent to the display area in a plan view;
a thin film transistor on the base substrate, and spaced from the hole;
a light emitting element comprising a pixel electrode at the display area, and connected to the thin film transistor;
a first insulating layer between the base substrate and the light emitting element, and having a groove pattern defined therein and overlapping with the hole area;
a first conductive pattern on the first insulating layer, overlapping with the hole area, and comprising a tip portion defining a first pattern hole overlapping with the groove pattern;
a second conductive pattern at a layer different from a layer of the first conductive pattern, overlapping with the hole area, and having a second pattern hole defined therethrough and overlapping with the first pattern hole; and
an electronic module overlapping with the hole area.

18. A method of manufacturing a display panel, comprising:
providing a target substrate comprising a base substrate, and a first insulating layer on the base substrate, the base substrate comprising a hole area, and a display area surrounding the hole area;
forming a first conductive pattern comprising a first pattern hole defined therethrough, the first pattern hole exposing a portion of the first insulating layer overlapping with the hole area;
forming a conductive layer covering the display area, the first conductive pattern, and the portion of the first insulating layer;
forming a preliminary second conductive pattern overlapping with the first pattern hole, and a pixel electrode spaced from the preliminary second conductive pattern, from the conductive layer;
forming a second conductive pattern from the preliminary second conductive pattern, the second conductive pattern comprising a second pattern hole defined therethrough, and overlapping with the first pattern hole; and
forming a groove pattern in the first insulating layer to overlap with the first pattern hole,
wherein the preliminary second conductive pattern covers a side surface of the first conductive pattern defining the first pattern hole.

19. The method of claim 18, wherein the second preliminary conductive pattern and the pixel electrode are formed by wet-etching the conductive layer, and the groove pattern is formed by dry-etching the first insulating layer.

20. The method of claim 18, wherein a side surface of the first conductive pattern defining the first pattern hole protrudes more toward a center of the first pattern hole than an inner side surface of the first insulating layer defining the groove pattern.
